(19) United States
(12) Patent Application Publication
(10) Pub. No.: US 2026/0190566 A1
(43) Pub. Date: Jul. 2, 2026

(54) Display Device and Light Emitting Device

(71) Applicant: LG Display Co., Ltd., Seoul (KR)

(72) Inventors: Dae-Il Kang, Paju-si (KR); Sungmoo Kim, Paju-si (KR)

(21) Appl. No.: 19/330,115

(22) Filed: Sep. 16, 2025

(30) Foreign Application Priority Data
Dec. 31, 2024 (KR) 10-2024-0202067

(51) Int. Cl. H10H 29/39

(52) U.S. Cl. CPC H10H 29/39

(57) ABSTRACT

A display device according to embodiments of the present disclosure may include a substrate, an insulating layer disposed on the substrate and having a groove, a first lower electrode disposed on the insulating layer, a first light emitting device disposed on the insulating layer and including a first electrode and a second electrode, a catching material disposed inside the groove, a second light emitting device disposed on the catching material and including a first electrode and a second electrode, and a second lower electrode disposed on the first lower electrode and connected to the first electrode of the second light emitting device.

### CROSS REFERENCE TO RELATED APPLICATION

This application claims priority from Korean Patent Application No. 10-2024-0202067, filed on Dec. 31, 2024, which is hereby incorporated by reference for all purposes as if fully set forth herein.

### TECHNICAL FIELD

Embodiments of the present disclosure relate to a display device and a light emitting device.

### BACKGROUND

Display devices are applied to various electronic devices such as TVs, mobile phones, laptops, and tablets. Display devices include organic light emitting displays (OLED) that emit light on their own and liquid crystal displays (LCD) that require a separate light source.

Recently, a display device including a light emitting diode (LED) has been attracting attention as a next-generation display device. Since a light emitting device or a light emitting diode is made of an inorganic material rather than an organic material, a display device including a light emitting diode may have a faster lighting speed, superior light emitting efficiency, and can display high-luminance images compared to a liquid crystal display or an organic light emitting display.

However, in the case of a display device with a light emitting device, there may be cases in which some of the light emitting devices transferred to a display panel are found to be defective.

### SUMMARY

Embodiments of the present disclosure may provide a display device having a structure that enables easy repair of a sub-pixel including a defective light emitting device if a defect occurs in a light emitting device disposed on a display panel.

Embodiments of the present disclosure may provide a display device having a structure capable of repairing both a dark spot defect and a bright spot defect of the light emitting device if a defect occurs in a light emitting device disposed on a display panel.

Embodiments of the present disclosure may provide a light emitting device having an electrode structure that facilitates repair processing.

Embodiments of the present disclosure may provide a light emitting device having a structure capable of side contact with an electrode on a display panel.

The objects of the embodiments of the present disclosure are not limited to the objects described in this disclosure, and other objects will be clearly understood by those skilled in the art from the description below.

A display device according to embodiments of the present disclosure may include a substrate, an insulating layer disposed on the substrate and having a groove, a first lower electrode disposed on the insulating layer, a first light emitting device disposed on the insulating layer and including a first electrode and a second electrode, a catching material disposed inside the groove, a second light emitting device disposed on the catching material and including a first electrode and a second electrode, and a second lower electrode disposed on the first lower electrode and connected to the first electrode of the second light emitting device.

A display device according to embodiments of the present disclosure may include a substrate, an insulating layer disposed on the substrate and having a groove, a first lower electrode disposed on the insulating layer, a first light emitting device disposed on the insulating layer and including a first electrode and a second electrode, at least one organic layer surrounding the first light emitting device and filling the interior of the groove, and an upper electrode disposed on the at least one organic layer.

A light emitting device according to embodiments of the present disclosure may include a first electrode, a first semiconductor layer on the first electrode, an emission layer on the first semiconductor layer, a second semiconductor layer on the emission layer, and a second electrode on the second semiconductor layer. The first electrode may includes a lower electrode having a first area, and an upper electrode disposed on the lower electrode and having a second area smaller than the first area.

A display device according to another embodiment comprises a first light emitting device including a first electrode and a second electrode; a second light emitting device including a third electrode and a fourth electrode; a driving transistor configured to drive the first light emitting device and/or the second light-emitting device; a first lower electrode electrically connected to the driving transistor, at least a part of the first lower electrode in contact with the first light emitting device, and the first lower electrode not in contact with the second light emitting device; and a second lower electrode disposed on the first lower electrode, at least a part of the second lower electrode in contact with the first light emitting device, and the second lower electrode also in contact with the second light emitting device.

In some embodiments, the first electrode of the first light emitting device includes a first part, and a second part on the first part, the first part being wider in size than the second part; the third electrode of the second light emitting device includes a third part, and a fourth part on the third part, the third part being wider in size than the fourth part; the at least part of the first lower electrode is in contact with the first part and the second part of the first electrode of the first light emitting device; and the at least a part of the second lower electrode is in contact with the first part and the second part of the first electrode of the first light emitting device, and the second lower electrode is also in contact with the third part and the fourth part of the third electrode of the second light emitting device.

In some embodiments, the second lower electrode is in contact with a side surface and a top surface of the third part and with a side surface of the fourth part.

In some embodiments, the first light emitting device is a defective light emitting device that does not emit normal light, and the second light emitting device is a normal light emitting device emitting normal light.

In some embodiments, each of the first light emitting device and the second light emitting device further includes a first protective film surrounding a side surface of a lower part of each of the first light emitting device and the second light emitting device; each of the first light emitting device and the second light emitting device further includes a second protective film surrounding a side surface of an upper part of each of the first light emitting device and the second light emitting device; and the first protective film and the second protective film protrude outwardly away from the first light emitting device and the second light emitting device while being in contact with each other at a boundary between the upper part and the lower part.

In some embodiments, another part of the first lower electrode other than at least the part of the first lower electrode is electrically disconnected from the first light emitting device.

According to embodiments of the present disclosure, it is possible to provide a display device having a structure that enables easy repair of a sub-pixel including a defective light emitting device if a defect occurs in a light emitting device disposed on a display panel.

According to embodiments of the present disclosure, it is possible to provide a display device having a structure capable of repairing both a dark spot defect and a bright spot defect of the light emitting device if a defect occurs in a light emitting device disposed on a display panel.

According to embodiments of the present disclosure, it is possible to provide a light emitting device having an electrode structure that facilitates repair processing.

According to embodiments of the present disclosure, it is possible to provide a light emitting device having a structure capable of side contact with an electrode on a display panel.

According to embodiments of the present disclosure, it is possible to archive the process optimization by effectively repairing sub-pixels having defective light emitting devices without significant changes to the panel structure.

According to embodiments of the present disclosure, since there is no need to adopt a redundancy structure for additionally transferring expensive light emitting devices in preparation for failure of light emitting devices, it is possible to reduce the size and the weight of the display panel, thereby simplifying the design of the display panel, and significantly lowering the product price of the display panel.

The effects of the embodiments of the present disclosure are not limited to the effects described in this disclosure, and other effects will be clearly understood by those skilled in the art from the description of the claims.

### BRIEF DESCRIPTION OF THE DRAWINGS

The present disclosure will be more fully understood from the detailed description and accompanying drawings provided below, which are provided for illustration purposes only and are not intended to limit the present disclosure.

FIG. 1 is a system configuration diagram of a display device according to embodiments of the present disclosure.

FIG. 2 is an equivalent circuit of a sub-pixel in a display device according to embodiments of the present disclosure.

FIG. 3, FIG. 4A, and FIG. 4B illustrate light emitting devices of a display device according to embodiments of the present disclosure.

FIG. 5A, FIG. 5B, FIG. 6, and FIG. 7 are cross-sectional views of a display panel according to embodiments of the present disclosure.

FIG. 8 to FIG. 16 illustrate a manufacturing process of a display panel according to embodiments of the present disclosure.

### DETAILED DESCRIPTION

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”

Hereinafter, various embodiments of the disclosure are described in detail with reference to the accompanying drawings.

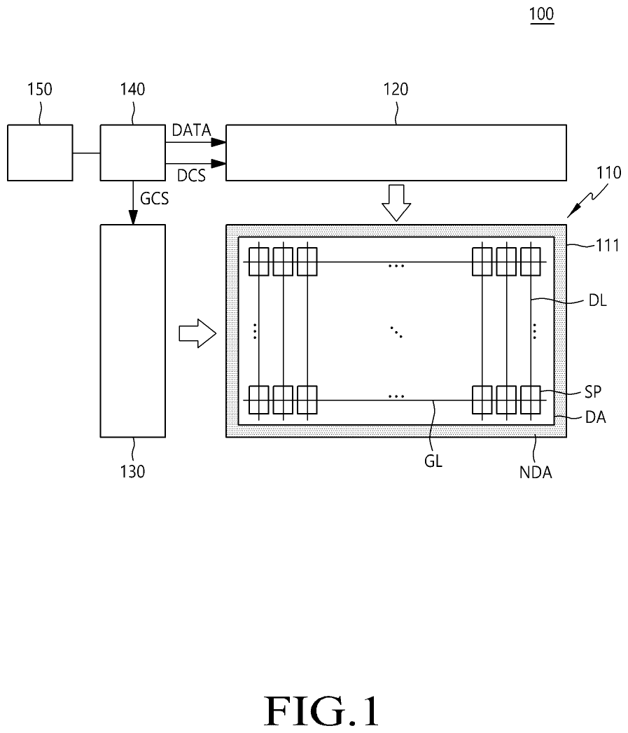

FIG. 1 is a system configuration diagram of a display device 100 according to embodiments of the present disclosure.

Referring to FIG. 1, a display device 100 according to the embodiments of the present disclosure may include a display panel 110 and a display driving circuit as components for displaying an image. The display driving circuit may be a circuit for driving the display panel 110. The display driving circuit may include a data driving circuit 120, a gate driving circuit 130, and a controller 140, but the embodiments of the present disclosure are not limited thereto.

The display panel 110 may include a substrate 111 and a plurality of sub-pixels SP arranged on the substrate 111.

The substrate 111 may include a display area DA and a non-display area NDA. The display area DA is an area where an image can be displayed, and may also be referred to as an active area. A plurality of sub-pixels SP for displaying an image may be arranged in the display area DA. The non-display area NDA is an area where an image is not displayed, and may be an outer area of the display area DA. The non-display area NDA may also be referred to as a bezel (or bezel area). The non-display area NDA may include a pad area.

The display device 100 according to the embodiments of the present disclosure may be a self-luminous display device in which the display panel 110 emits light by itself.

Each of the plurality of sub-pixels SP arranged on the display panel 110 of the display device 100 according to the embodiments of the present disclosure may include a light emitting device that emits light by itself. Each of the plurality of sub-pixels SP arranged on the display panel 110 of the display device 100 according to the embodiments of the present disclosure may include at least one transistor for driving the light emitting device, and may further include at least one capacitor. However, the present disclosure is not limited thereto.

Various types of signal lines for driving a plurality of sub-pixels SP may be arranged on the substrate 111 of the display panel 110. For example, the various types of signal lines may include a plurality of data lines DL that transmit data signals (also referred to as data voltages or image signals) and a plurality of gate lines GL that transmit gate signals (also referred to as scan signals).

For example, the plurality of data lines DL and the plurality of gate lines GL may intersect each other. Each of the plurality of data lines DL may be arranged while extending in a column direction, and each of the plurality of gate lines GL may be arranged while extending in a row direction. According to embodiments of the present disclosure, the column direction and the row direction may be relative directions. For example, the column direction may be the row direction depending on the viewpoint, and the row direction may be the column direction depending on the viewpoint. Hereinafter, for convenience of explanation, it will be described an example in which each of the plurality of data lines DL is arranged in the column direction, and each of the plurality of gate lines GL is arranged in the row direction, but the embodiments of the present disclosure are not limited thereto. In the embodiments of the present disclosure, an angle formed by the row direction and the column direction may be orthogonal (or 90 degrees) or may be an angle different from the orthogonal angle. In addition, in the embodiments of the present disclosure, the row direction may be referred to as a first direction, and the column direction may be referred to as a second direction.

The data driving circuit 120 may be a circuit for driving the plurality of data lines DL, and may output a data signal corresponding to an image signal to the plurality of data lines DL.

The data driving circuit 120 may receive image data DATA in digital form from the controller 140, convert the received image data DATA into an analog data signal (or also referred to as a data voltage), and output the converted data signals to the plurality of data lines DL.

For example, the data driving circuit 120 may be connected to the display panel 110 in a tape automated bonding (TAB) manner, connected to the bonding pad of the display panel 110 in a chip-on-glass (COG) or chip-on-panel (COP) manner, or implemented in a chip-on-film (COF) manner and connected to the display panel 110, but is not limited thereto.

The data driving circuit 120 may be connected to one side (e.g., the upper side or the lower side) of the display panel 110. For another example, depending on the driving method or panel design method, the data driving circuit 120 may be connected to both sides (e.g., the upper side and the lower side) of the display panel 110, or connected to two or more of the four sides of the display panel 110.

The data driving circuit 120 may be connected to the outside of the display area DA of the display panel 110, but as another example, may be disposed in the display area DA of the display panel 110.

The gate driving circuit 130 is a circuit for driving a plurality of gate lines GL, and may output gate signals to a plurality of gate lines GL.

The gate driving circuit 130 may receive a first gate voltage corresponding to a turn-on voltage (also referred to as a turn-on level voltage) and a second gate voltage corresponding to a turn-off voltage (also referred to as a turn-off level voltage) along with various gate driving control signals GCS, generate gate signals including a section having the first gate voltage and a section having the second gate voltage for a predetermined period of time (e.g., one frame time), and supply the generated gate signals to a plurality of gate lines GL. As an example, the turn-on level voltage may be a high level voltage, and the turn-off level voltage may be a low level voltage. As another example, the turn-on level voltage may be a low level voltage, and the turn-off level voltage may be a high level voltage.

In the display device 100 according to the embodiments of the present disclosure, the gate driving circuit 130 may be built into the display panel 110 as a gate-in-panel (GIP) type, but the embodiments of the present disclosure are not limited thereto. If the gate driving circuit 130 is a gate-in-panel type, the gate driving circuit 130 may be formed on the substrate 111 of the display panel 110 during the manufacturing process of the display panel 110. If the gate driving circuit 130 is a gate-in-panel type, the gate driving circuit 130 may be referred to as a gate-in-panel circuit (GIPC).

For example, the gate driving circuit 130 may be disposed in a non-display area NDA of the display panel 110.

For another example, the gate driving circuit 130 may be disposed in a display area DA of the display panel 110. For example, the gate driving circuit 130 may be disposed in a first partial area (e.g., a left area or a right area within the display area DA) within the display area DA. As another example, the gate driving circuit 130 may be arranged in a first partial area (e.g., a left area or a right area within the display area DA) and a second partial area (e.g., a right area or a left area within the display area DA) within the display area DA. As another example, the gate driving circuit 130 may be arranged over the entire area of the display area DA

The gate driving circuit 130 of the gate-in-panel type may include a plurality of transistors. Each of the plurality of transistors included in the gate driving circuit 130 may include an active layer including a first semiconductor material, and each of the plurality of transistors included in the sub-pixels SP may include an active layer including a second semiconductor material. As an example, the first semiconductor material and the second semiconductor material may be substantially the same. In another example, the first semiconductor material and the second semiconductor material may be different from each other. For example, the first semiconductor material may be a silicon-based semiconductor material (e.g., low temperature poly silicone; LTPS), and the second semiconductor material may be an oxide semiconductor material. For example, the active layer may be a semiconductor layer, but is not limited thereto.

The controller 140 is a device for controlling the data driving circuit 120 and the gate driving circuit 130, and may control the driving timing for a plurality of data lines DL and the driving timing for a plurality of gate lines GL.

The controller 140 may supply a data driving control signal DCS to the data driving circuit 120 to control the data driving circuit 120, and may supply a gate driving control signal GCS to the gate driving circuit 130 to control the gate driving circuit 130.

The controller 140 may receive input image data from a host system 150, and supply image data DATA to the data driving circuit 120 based on the input image data.

The controller 140 may be implemented as a separate component from the data driving circuit 120, or may be implemented as an integrated circuit by being integrated with the data driving circuit 120.

The controller 140 may be mounted on a printed circuit board or a flexible printed circuit, and may be electrically connected to the data driving circuit 120 and the gate driving circuit 130 through the printed circuit board or the flexible printed circuit.

The display device 100 according to the embodiments of the present disclosure may be a mobile terminal such as a smart phone or a tablet, or a monitor or television (TV) of various sizes, and may be a display of various types and sizes capable of displaying information or images, without being limited thereto.

The display device 100 according to the embodiments of the present disclosure may further include an electronic device such as a camera (e.g., image sensor) or a detection sensor. For example, the detection sensor may be a sensor that detects an object or a human body by receiving light such as infrared, ultrasonic, or ultraviolet, but the embodiments of the present disclosure are not limited thereto.

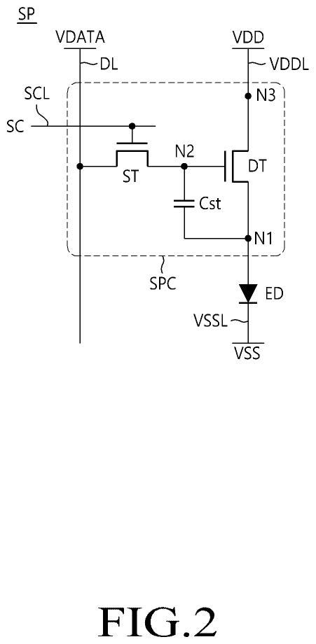

FIG. 2 is an equivalent circuit of a sub-pixel SP of the display device 100 according to the embodiments of the present disclosure.

Referring to FIG. 2, each of the plurality of sub-pixels SP may include a light emitting device ED and a sub-pixel circuit SPC configured to drive the light emitting device ED.

The light emitting device ED may include a first electrode and a second electrode. The first electrode may be connected to the sub-pixel circuit SPC. The second electrode may be connected to a common voltage line to which a common voltage is applied.

For example, the first electrode may be a pixel electrode provided in each sub-pixel SP, and the second electrode may be a common electrode. For example, the first electrode may be an anode electrode, and the second electrode may be a cathode electrode. For another example, the first electrode may be a cathode electrode, and the second electrode may be an anode electrode.

The common voltage required to drive the sub-pixel SP may include a low-potential common voltage VSS and a high-potential common voltage VDD. In order to drive the sub-pixel SP, the common voltage line connected to the sub-pixel SP may include a low-potential common voltage line VSSL to which the low-potential common voltage VSS is applied, and a high-potential common voltage line VDDL to which the high-potential common voltage VDD is applied.

The low-potential common voltage VSS and the low-potential common voltage line VSSL may be also referred to as a base voltage and a base voltage line, and the high-potential common voltage VDD and the high-potential common voltage line VDDL may be also referred to as a driving voltage VDD and a driving voltage line VDDL.

For example, as shown in FIG. 2, a light emitting device ED may be connected between a driving transistor DT and the low-potential common voltage line VSSL. In this case, the second electrode of the light emitting device ED may be electrically connected to the low-potential common voltage line VSSL. The first electrode of the light emitting device ED may be electrically connected to the sub-pixel circuit SPC.

In another example, the light emitting device ED may be connected between the high-potential common voltage line VDDL and the driving transistor DT. In this case, the first electrode of the light emitting device ED may be electrically connected to a high-potential common voltage line VDDL. The second electrode of the light emitting device ED may be electrically connected to a sub-pixel circuit SPC.

For example, the light emitting device ED may include an inorganic-based light emitting diode (LED). For example, the inorganic-based light emitting diode (LED) may also be referred to as a micro light emitting diode (micro LED).

The sub-pixel circuit SPC may include a driving transistor DT, a scan transistor ST, and a storage capacitor Cst.

The driving transistor DT may be a transistor for supplying a driving current to the light emitting device ED. For example, the driving transistor DT may be connected between a common voltage line (e.g., a high-potential common voltage line VDDL or a low-potential common voltage line VSSL) and the light emitting device ED.

The driving transistor DT may include a first node N1, a second node N2, and a third node N3. For example, the first node N1 of the driving transistor DT may be electrically connected to a first electrode of the light emitting device ED, the second node N2 of the driving transistor DT may be applied with a data signal VDATA, and the third node N3 of the driving transistor DT may be electrically connected to the high-potential common voltage line VDDL.

For example, in the driving transistor DT, the second node N2 may be a gate node, the first node N1 may be a source node or a drain node, and the third node N3 may be a drain node or a source node.

The scan transistor ST may be a switching transistor for transmitting a data signal (VDATA) corresponding to an image signal to the second node N2, which is a gate node of the driving transistor DT.

For example, the scan transistor ST may be turned on and off by a scan signal SC, which is a type of gate signal applied through a scan line SCL, which is a type of gate line GL, so as to control the electrical connection between the second node N2 of the driving transistor DT and the data line DL. The drain electrode or the source electrode of the scan transistor ST may be electrically connected to the data line DL, the source electrode or the drain electrode of the scan transistor ST may be electrically connected to the second node N2 of the driving transistor DT, and the gate electrode of the scan transistor ST may be electrically connected to a scan line SCL.

The storage capacitor Cst may be electrically connected between the first node N1 and the second node N2 of the driving transistor DT. The storage capacitor Cst may include at least one capacitor electrode electrically connected to the first node N1 of the driving transistor DT or corresponding to the first node N1 of the driving transistor DT, and at least one capacitor electrode electrically connected to the second node N2 of the driving transistor DT or corresponding to the second node N2 of the driving transistor DT.

The storage capacitor Cst may be an external capacitor intentionally designed outside the driving transistor DT, rather than a parasitic capacitor (e.g., Cgs, Cgd) that may exist between the first node N1 and the second node N2 of the driving transistor DT. Each of the driving transistor DT and the scan transistor ST may be an n-type transistor or a p-type transistor.

For example, the semiconductor material included in the active layer of the driving transistor DT and the semiconductor material included in the active layer of the scan transistor ST may be the same. For example, the semiconductor material included in the active layer of each of the driving transistor DT and the scan transistor ST may be an oxide semiconductor material or a silicon-based semiconductor material (e.g., low temperature poly silicone).

For another example, the semiconductor material included in the active layer of the driving transistor DT and the semiconductor material included in the active layer of the scan transistor ST may be different from each other. For example, the semiconductor material included in the active layer of the driving transistor DT may be an oxide semiconductor material, and the semiconductor material included in the active layer of the scan transistor ST may be a silicon-based semiconductor material (e.g., LTP), but is not limited thereto.

The sub-pixel circuit SPC may have a 2T (Transistor) 1C (Capacitor) structure including two transistors DT and ST and one capacitor Cst as illustrated in FIG. 2, and may further include one or more transistors or one or more capacitors, depending on the case. For example, the sub-pixel circuit SPC may have a structure including three to four transistors and one capacitor Cst. As another example, the sub-pixel circuit SPC may have a structure including 5 to 9 transistors and 1 or more capacitors Cst, however, is not limited thereto.

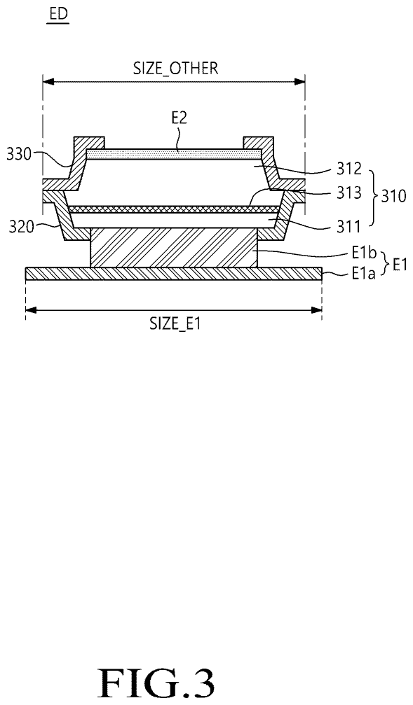

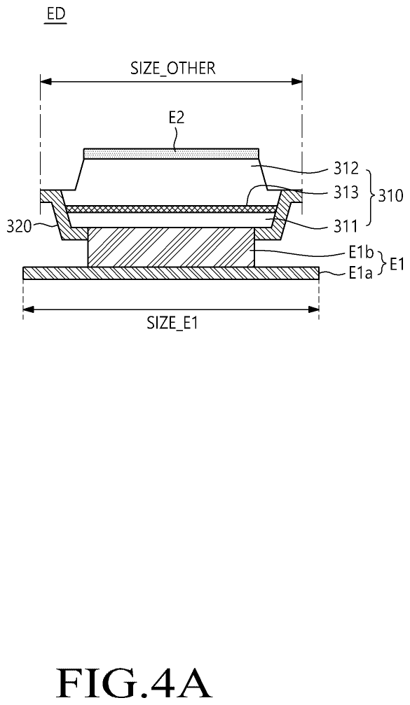

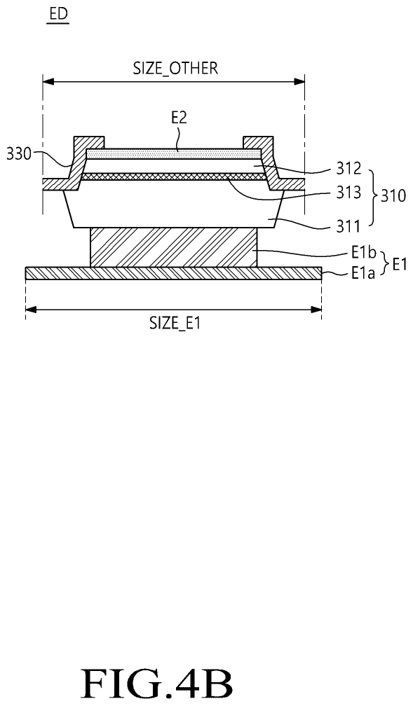

As an example, the light emitting device ED may be a vertical light-emitting diode (see FIGS. 3 and 4). As another example, the light emitting device ED may be a flip type light-emitting diode. As another example, the light emitting device ED may be a lateral type light-emitting diode, however, is not limited thereto. Hereinafter, the light emitting device ED will be described as an example of a vertical light-emitting diode.

FIGS. 3, 4A, and 4B illustrate light emitting devices ED of a display device 100 according to embodiments of the present disclosure.

Referring to FIG. 3, FIG. 4A and FIG. 4B, the light emitting device ED may include a first electrode E1 and a second electrode E2, and an intermediate layer 310 between the first electrode E1 and the second electrode E2. The intermediate layer 310 may include a first semiconductor layer 311 disposed on the first electrode E1, an emission layer 313 disposed on the first semiconductor layer 311, and a second semiconductor layer 312 disposed on the emission layer 313.

As an example, referring to FIG. 3 and FIG. 4A, the first electrode E1 may be an anode electrode, and the second electrode E2 may be a cathode electrode. As another example, referring to FIG. 4B, the first electrode E1 may be a cathode electrode, and the second electrode E2 may be an anode electrode. Here, the anode electrode may be also called a p-electrode (here, “p” means hole), and the cathode electrode may be also called an n-electrode (here, “n” means electron).

For example, a pixel voltage supplied to a sub-pixel circuit SPC of a corresponding sub-pixel SP may be applied to the first electrode E1, and a common voltage (e.g., a low-potential common voltage VSS) may be applied to the second electrode E2. Here, the pixel voltage may be a voltage that varies depending on the image or driving state.

For another example, a common voltage (e.g., a high-potential common voltage VDD) may be applied to the first electrode E1, and a pixel voltage supplied to a sub-pixel circuit SPC of a corresponding sub-pixel SP may be applied to the second electrode E2. Here, the pixel voltage may be a voltage that varies depending on the image or driving state.

For example, the first electrode E1 may include at least one of gold (Au), copper (Cu), tin (Sn), titanium (Ti), aluminum (Al), and silver (Ag). For example, the second electrode E2 may be made of a transparent metal material (e.g., Transparent Conductive Material; TCO) such as ITO (Indium Tin Oxide) and IZO (Indium Zinc Oxide) capable of transmitting light.

The first semiconductor layer 311 may be disposed on the first electrode E1. For example, the first semiconductor layer 311 may be a p-type semiconductor and may include a semiconductor material having a chemical formula of AlxGayIn1-x-yN (0≤x≤1, 0≤y≤1, 0≤x+y≤1), but is not limited thereto. For example, the semiconductor material included in the first semiconductor layer 311 may be at least one of p-type doped AlGaInN, GaN, AlGaN, InGaN, AlN, and InN, but is not limited thereto. The first semiconductor layer 311 may be doped with a p-type dopant, and the p-type dopant may be Mg, Zn, Ca, Se, or Ba, but is not limited thereto. For example, the first semiconductor layer 311 may be p-GaN doped with p-type Mg, but is not limited thereto.

Meanwhile, the light emitting device ED may further include an electron blocking layer disposed on the first semiconductor layer 311. The electron blocking layer may be a layer for suppressing or preventing too many electrons from flowing to the emission layer 313. For example, the electron blocking layer may be p-AlGaN doped with p-type Mg, but is not limited thereto. The electron blocking layer may be omitted.

The emission layer 313 may be also referred to as an active layer, and may be disposed on the first semiconductor layer 311 or the electron blocking layer. The emission layer 313 may emit light by the combination of electron-hole pairs according to an electric signal applied through the first semiconductor layer 311 and the second semiconductor layer 312. The emission layer 313 may emit one of the first color light, the second color light, and the third color light. For example, the first color light may be red light, the second color light may be green light, and the third color light may be blue light.

The emission layer 313 may include a material having a single or multiple quantum well structure. If the emission layer 313 includes a material having a multi-quantum well (MQW) structure, the emission layer may have a structure in which multiple well layers and barrier layers are alternately laminated. In this case, the well layer may be formed of InGaN, and the barrier layer may be formed of GaN or AlGaN, but is not limited thereto.

Alternatively, the emission layer 313 may have a structure in which semiconductor materials having a large band gap energy and semiconductor materials having a small band gap energy are alternately laminated, and may include different group III to group V semiconductor materials depending on the wavelength of the light emitted. For example, if indium is included among the semiconductor materials included in the emission layer 313, the color of the light emitted may vary depending on the content of indium. For example, as the content of indium increases, light in a longer wavelength band may be emitted. For example, if the content of indium is about 15%, light in a blue wavelength band may be emitted, if the content of indium is about 25%, light in a green wavelength band may be emitted, and if the content of indium is about 35% or more, light in a red wavelength band may be emitted.

Meanwhile, the light emitting device ED may further include a superlattice layer disposed on the emission layer 313. The superlattice layer may be a layer for relieving stress between the second semiconductor layer 312 and the emission layer 313. For example, the superlattice layer may be formed of InGaN or GaN. The superlattice layer may be omitted.

The second semiconductor layer 312 may be disposed on the emission layer 313 or the superlattice layer. For example, the second semiconductor layer 312 may be an n-type semiconductor and may include a semiconductor material having a chemical formula of AlxGayIn1-x-yN (0≤x≤1, 0≤y≤1, 0≤x+y≤1), but is not limited thereto. For example, the semiconductor material included in the second semiconductor layer 312 may be at least one of n-type doped AlGaInN, GaN, AlGaN, InGaN, AlN, and InN, but is not limited thereto. For example, the second semiconductor layer 312 may be doped with an n-type dopant, and the n-type dopant may be Si, Ge, Sn, etc., but is not limited thereto. For example, the second semiconductor layer 312 may be n-GaN doped with n-type Si, but is not limited thereto.

The first electrode E1 may be composed of a single electrode layer or multiple electrode layers.

If the first electrode E1 is composed of multiple electrode layers, the first electrode E1 may include a lower electrode E1a having a first area, and an upper electrode E1b disposed on the lower electrode E1a and having a second area smaller than the first area. The upper electrode E1b may have a smaller area than the first semiconductor layer 311. As a result, there may be formed an undercut structure in which the lower portion of the first semiconductor layer 311 is sunken. As a result, during the panel manufacturing process, after the light emitting device ED is transferred, a metal (e.g., a second lower electrode LE2) or an insulating layer deposited on the light emitting device ED may be cut off or disconnected around the light emitting device ED.

The light emitting device ED may further include a protective film covering the entire or part of a side surface of the intermediate layer 310.

Referring to FIG. 3, the protective film of the light emitting device ED may include a first protective film 320 covering the side surface and part of the lower surface of the first semiconductor layer 311 and the side surface of the emission layer 313. The first protective film 320 may also cover the side surface of a part of the second semiconductor layer 312.

The first protective film 320 may cover a side surface of a part of the first electrode E1. For example, the first protective film 320 may cover a side surface of a part of the upper electrode E1b of the first electrode E1, and may not cover a side surface of the lower electrode E1a of the first electrode E1. The upper surface of the lower electrode E1a of the first electrode E1 of the light emitting device ED may be spaced apart from the first protective film 320.

The first protective film 320 may have a hole, and at least a part of the first semiconductor layer 311 may be exposed through the hole of the first protective film 320. The first semiconductor layer 311 and the first electrode E1 may be connected at a portion where the first semiconductor layer 311 is exposed through the hole of the first protective film 320. For example, through the hole of the first protective film 320, the upper electrode E1b of the first electrode E1 may be connected to the first semiconductor layer 311.

For example, as shown in FIGS. 3 and 4A, the second semiconductor layer 312 may be formed thicker than the first semiconductor layer 311, so that the emission layer 313 may be disposed closer to the first electrode E1 than to the second electrode E2. In this case, the first electrode E1 may be a p-electrode. As another example, as shown in FIG. 4B, the second semiconductor layer 312 may be formed thinner than the first semiconductor layer 311, so that the emission layer 313 may be disposed closer to the second electrode E2 than to the first electrode E1. In this case, the second electrode E2 may be a p-electrode.

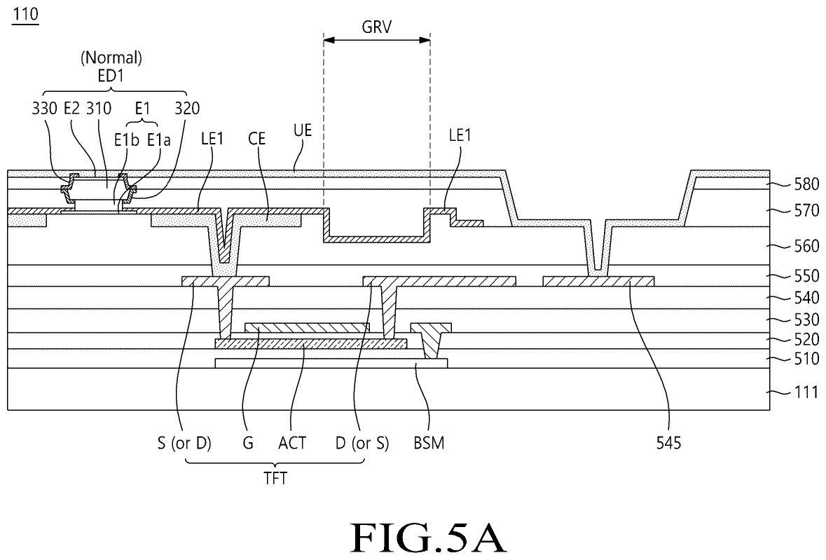

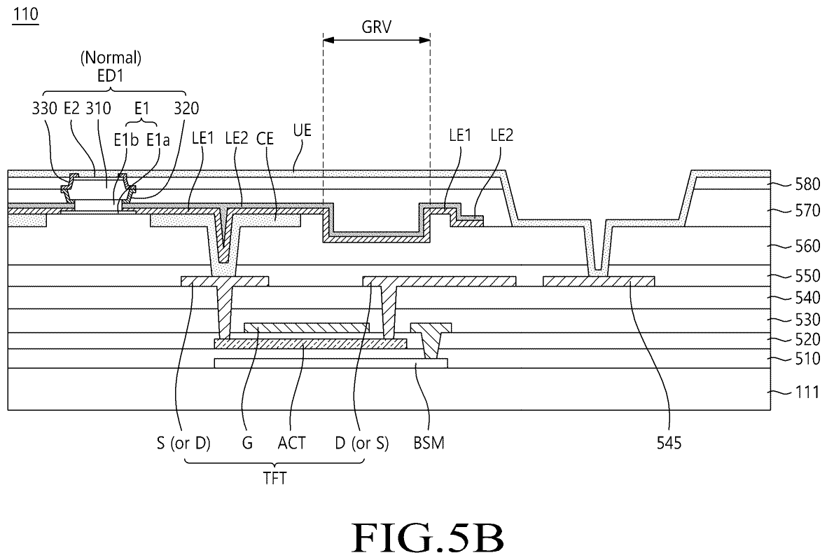

Referring to FIG. 3, the protective film of the light emitting device ED may include a second protective film 330 covering the side surface of the second semiconductor layer 312. The second protective film 330 may cover the entire side surface of the second electrode E2 and a portion of the upper surface of the second electrode E2. The second protective film 330 may have a hole, and at least a portion of the second electrode E2 may be exposed through the hole of the second protective film 330. The portion of the second electrode E2 exposed through the hole of the second protective film 330 may be connected to another electrode (for example, an upper electrode UE in FIG. 5A) located above the second electrode E2.

Referring to FIG. 3, the first protective film 320 may be disposed on a first side portion (e.g., a lower side portion) of the intermediate layer 310, and the second protective film 330 may be disposed on a second side portion (e.g., an upper side portion) of the intermediate layer 310. The first protective film 320 and the second protective film 330 may be in contact at a boundary between the first side portion and the second side portion. The first protective film 320 and the second protective film 330 may be protruded toward the outer side of the light emitting device ED while in contact at the boundary between the first side portion and the second side portion. Accordingly, the sealing characteristic of the light emitting device ED with respect to the intermediate layer 310 may be improved. In addition, an undercut structure may be formed in which a lower portion of the first protective film 320 is sunken toward the center of the light emitting device ED. Due to this, after the light emitting device ED is formed, the metal (e.g., the second lower electrode LE2) or the insulating layer deposited on the light emitting device ED can be cut off around the light emitting device ED.

Referring to FIG. 4A, the protective film of the light emitting device ED may include a first protective film 320 covering each side of the first semiconductor layer 311 and the emission layer 313, but may not include a second protective film 330 covering the side of the second semiconductor layer 312. In this case, the emission layer 313 may be positioned closer to the first electrode E1 than to the second electrode E2, and the first protective film 320 may cover the side of the emission layer 313.

Referring to FIG. 4B, the protective film of the light emitting device ED may include a second protective film 330 covering the side surface of the second semiconductor layer 312, but may not include a first protective film 320 covering each side surface of the first semiconductor layer 311 and the emission layer 313. In this case, the emission layer 313 may be positioned closer to the second electrode E2 than to the first electrode E1, and the second protective film 330 may cover the side surface of the emission layer 313.

As illustrated in FIG. 4B, since the lower first protective film 320 among the first protective film 320 and the second protective film 330 is omitted, an undercut structure in which the lower surface of the intermediate layer 310 is more significantly sunken may be effectively formed. As a result, a more accurate disconnection structure may be formed for the metal or insulating layer deposited after the light emitting device ED is transferred.

Referring to FIG. 3, FIG. 4A, and FIG. 4B, the size SIZE_E1 of the first electrode E1 may be equal to or larger than the chip size of the light emitting device ED. In addition, the size SIZE_E1 of the first electrode E1 may be larger than the size SIZE_OTHER of a portion other than the first electrode E1 of the light emitting device ED. Here, the size SIZE_OTHER of a portion other than the first electrode E1 of the light emitting device ED may be an area inside the outer edge of the protective film 320 and 330, or an area inside the outer edge of the intermediate layer 310. The size SIZE_E1 of the first electrode E1 may be the area of the first electrode E1. The size SIZE_E1 of the first electrode E1 may be the first area of the lower electrode E1a.

According to embodiments of the present disclosure, the size SIZE_E1 of the first electrode E1 of the light emitting device ED is designed to be equal to or larger than the chip size of the light emitting device ED, or the size SIZE_E1 of the first electrode E1 of the light emitting device ED is designed to be larger than the size SIZE_OTHER of another part, so that, if a defect occurs in the light emitting device ED, it is possible to facilitate the repair processing for the sub-pixel SP including a defective light emitting device ED.

The upper electrode E1b may have a height greater than a height of the lower electrode E1a.

According to the embodiments of the present disclosure, since the upper surface of the lower electrode E1a of the first electrode E1 of the light emitting device ED is separated from the first protective film 320, if a defect occurs in the light emitting device ED, it is possible to facilitate the repair processing for the sub-pixel SP including the defective light emitting device ED.

Hereinafter, a display panel 110 including the light emitting device ED of FIG. 3 will be described in more detail. In the following description, FIGS. 1 to 4A and 4B will be referred to together.

FIGS. 5A and 5B are cross-sectional views of a display panel 110 according to embodiments of the present disclosure.

FIGS. 5A and 5B are cross-sectional views of a display panel 110 manufactured by determining that a first light emitting device ED1 included in a first sub-pixel SP is normal during an inspection process performed during the manufacturing process of the display panel 110.

FIG. 5A is a cross-sectional view of a display panel 110 that has been manufactured without any repair processing since the first light emitting device ED1 included in the first sub-pixel SP is determined to be normal and all light emitting devices included in other sub-pixels SP are determined to be normal.

FIG. 5B is a cross-sectional view of a display panel 110 that has been manufactured by performing the repair processing for a second sub-pixel in the case that the first light emitting device ED1 included in the first sub-pixel SP is determined to be normal but the light emitting device included in the second sub-pixel among other sub-pixels SP is determined to be defective. Referring to FIGS. 5A and 5B, a display panel 110 according to embodiments of the present disclosure may include a substrate 111, an insulating layer 560 disposed on the substrate 111 and having a plurality of grooves GRV, a first lower electrode LE1 disposed on the insulating layer 560, a first light emitting device ED1 disposed on the insulating layer 560 and including a first electrode E1 and a second electrode E2, at least one organic layer 570 and 580 disposed to surround the first light emitting device ED1 and fill an interior of a groove GRV adjacent to the first light emitting device ED1 among the plurality of grooves GRV of the insulating layer 560, and an upper electrode UE disposed on the organic layer 570 and 580.

The insulating layer 560 may have a plurality of grooves GRV. Each of the plurality of grooves GRV formed in the insulating layer 560 may exist for each sub-pixel SP. In some cases, two or more grooves GRV among the plurality of grooves GRV formed in the insulating layer 560 may exist for each sub-pixel SP. Each of the plurality of grooves GRV formed in the insulating layer 560 may be a repair site for repairing the corresponding sub-pixel SP, and may be an area where a light emitting device to replace a defective light emitting device included in the corresponding sub-pixel SP is transferred during the repair process. The groove GRV adjacent to the first light emitting device ED1 may be a groove GRV located in the area of the first sub-pixel SP among the plurality of grooves GRV formed in the insulating layer 560, and may be a groove GRV provided for repairing the first sub-pixel SP.

The first light emitting device ED1 may be disposed on the insulating layer 560, may be located outside the groove GRV, and may be disposed adjacent to the groove GRV.

The first light emitting device ED1 is included in the first sub-pixel SP and may be a light emitting device capable of normal light emission. The first light emitting device ED1 may be a light emitting device determined to be a normal light emitting device in an inspection process performed during the panel manufacturing process.

The first lower electrode LE1 may be positioned on the insulating layer 560 and may be connected by extending into the groove GRV. That is, the first lower electrode LE1 may not be disconnected inside the groove GRV of the insulating layer 560. For example, the first lower electrode LE1 may be formed of a transparent electrode and may be formed of a transparent metal material (e.g., transparent conductive material; TCO) such as ITO (Indium Tin Oxide) and IZO (Indium Zinc Oxide) that can transmit light, but is not limited thereto.

At least one organic layer may include a first organic layer 570 and a second organic layer 580 on the first organic layer 570. The first organic layer 570 may surround the first protective film 320, and the second organic layer 580 may surround the second protective film 330.

The insulating layer 560 may also be referred to as an adhesive layer.

The display panel 110 may further include a connection electrode CE disposed on the insulating layer 560. The connection electrode CE may be disposed below the first lower electrode LE1 and may be connected to the first lower electrode LE1. For example, the connection electrode CE may be a reflective electrode.

The display panel 110 may further include a transistor TFT included in a sub-pixel circuit SPC for driving the first light emitting device ED1.

The transistor TFT may include an active layer ACT, a source electrode S, a drain electrode D, and a gate electrode G.

The source electrode S or the drain electrode D of the transistor TFT may be electrically connected to the connection electrode CE. That is, the source electrode S or the drain electrode D of the transistor TFT may be electrically connected to the first lower electrode LE1 through the connection electrode CE.

In order to form the transistor TFT, the display panel 110 may further include insulating layers including a gate insulating layer 520, at least one interlayer insulating layer 530 and 540 on the gate insulating layer 520, and a passivation layer 550 on the at least one interlayer insulating layer 530 and 540. The insulating layer 560 may be disposed on the passivation layer 550.

The active layer ACT may be disposed on the substrate 111.

The gate insulating layer 520 may be disposed on the active layer ACT.

The gate electrode G may be disposed on the gate insulating layer 520.

At least one interlayer insulating layer 530 and 540 may be disposed on the gate electrode G. For example, at least one interlayer insulating layer 530 and 540 may include a first interlayer insulating layer 530 disposed on the gate electrode G and a second interlayer insulating layer 540 disposed on the first interlayer insulating layer 530.

The source electrode S and the drain electrode D may be disposed on the second interlayer insulating layer 540.

The source electrode S may be connected to a portion of the active layer ACT through a hole in the second interlayer insulating layer 540, the first interlayer insulating layer 530, and the gate insulating layer 520.

The drain electrode D may be connected to another portion of the active layer ACT through another hole in the second interlayer insulating layer 540, the first interlayer insulating layer 530, and the gate insulating layer 520.

The passivation layer 550 may be disposed on the source electrode S and the drain electrode D.

The insulating layer 560 may be disposed on the passivation layer 550.

The connection electrode CE may be electrically connected to the source electrode S or the drain electrode D of the transistor TFT through a hole of the insulating layer 560 and the passivation layer 550.

The display panel 110 may further include a power line 545 to which a common voltage is applied. For example, the common voltage applied to the power line 545 may be a low-potential common voltage VSS. In this case, the power line 545 may be a low-potential common voltage line VSSL or a wiring connected thereto. For another example, the common voltage applied to the power line 545 may be a high-potential common voltage VDD. In this case, the power line 545 may be a high-potential common voltage line VDDL or a wiring connected thereto.

The power line 545 may be arranged under the insulating layer 560. The upper electrode UE may be electrically connected to the power line 545 through a hole of the second organic layer 580, the first organic layer 570, and the insulating layer 560. For example, the power line 545 may be arranged between the second interlayer insulating layer 540 and the passivation layer 550, and the upper electrode UE may be electrically connected to the power line 545 through a hole of the second organic layer 580, the first organic layer 570, the insulating layer 560, and the passivation layer 550.

In the display panel 110, light emitted from the first light emitting device ED1 may be emitted in an upward direction opposite to the direction toward the substrate 111. Here, the upward direction may be a direction from the first electrode E1 toward the second electrode E2.

Referring to FIGS. 5A and 5B, the display panel 110 may further include a buffer layer 510 between the substrate 111 and the gate insulating layer 520, and a shield metal BSM disposed between the substrate 111 and the buffer layer 510 and overlapping with the active layer ACT of the transistor TFT.

The transistor TFT of FIGS. 5A and 5B may be a transistor included in the sub-pixel circuit SPC and connected to the first light emitting device ED1. For example, the transistor TFT of FIGS. 5A and 5B may be a driving transistor DT or a switching transistor. Here, the switching transistor may be a transistor that is turned on or off by a scan signal or an emission control signal, and may be connected to one of the first to third nodes of the driving transistor DT.

Referring to FIGS. 5A and 5B, the first electrode E1 of the first light emitting device ED1 may be electrically connected to the first lower electrode LE1. The second electrode E2 of the first light emitting device ED1 may be electrically connected to the upper electrode UE.

In a structure in which the first electrode E1 of the first light emitting device ED1 and the first lower electrode LE1 are connected, the back surface of the first electrode E1 of the first light emitting device ED1 and the upper surface of the first lower electrode LE1 may be not connected, but the side surface and upper surface of the first electrode E1 of the first light emitting device ED1 may be connected to the first lower electrode LE1. This connection structure may be referred to as a side contact structure.

For example, the first electrode E1 of the first light emitting device ED1 may be an anode electrode, and the second electrode E2 of the first light emitting device ED1 may be a cathode electrode. In this case, the first lower electrode LE1 may be an anode wiring, and the upper electrode UE may be a cathode wiring.

For another example, the first electrode E1 of the first light emitting device ED1 may be a cathode electrode, and the second electrode E2 of the first light emitting device ED1 may be an anode electrode. In this case, the first lower electrode LE1 may be a cathode wiring, and the upper electrode UE may be an anode wiring.

Referring to FIGS. 5A and 5B, the first electrode E1 of the first light emitting device ED1 may have the largest size in the first light emitting device ED1.

The first electrode E1 may include a lower electrode E1a disposed on an insulating layer 560 and an upper electrode E1b disposed on the lower electrode E1a. The lower electrode E1a may have a first area, and the upper electrode E1b may have a second area smaller than the first area.

Among the plurality of grooves GRV of the insulating layer 560, the groove GRV formed in the area of the first sub-pixel SP including the first light emitting device ED1 may be a space where a light emitting device to replace the first light emitting device ED1 is transferred during the repair process for the first sub-pixel SP. That is, the groove GRV of the insulating layer 560 may be a space scheduled as a repair site. If the repair process is not performed, the groove GRV of the insulating layer 560 may be filled with the first organic layer 570.

Referring to FIG. 5A, if the first light emitting device ED1 included in the first sub-pixel is determined to be normal during the panel manufacturing process, and the light emitting devices included in other sub-pixels are all determined to be normal, no repair processing is performed at all. Accordingly, in the display panel 110 that has been manufactured, only the first lower electrode LE1 may be connected to the first electrode E1 of the normal first light emitting device ED1.

Referring to FIG. 5B, if the first light emitting device ED1 included in the first sub-pixel is determined to be normal during the panel manufacturing process, but the light emitting device included in a second sub-pixel among other sub-pixels is determined to be defective, repair processing may be performed on the second sub-pixel. Accordingly, in the display panel 110 in which the manufacturing is completed, both the first lower electrode LE1 and the second lower electrode LE2 may be connected to the first electrode E1 of the normal first light emitting device ED1.

FIG. 6 is a cross-sectional view of a display panel 110 according to embodiments of the present disclosure.

FIG. 6 is a cross-sectional view of a display panel 110 in which the first light emitting device ED1 included in the first sub-pixel SP is determined to be defective during an inspection process performed during the manufacturing process of the display panel 110, and repair processing is performed on the first sub-pixel SP. In the following description, FIG. 5A and FIG. 5B are also referred to. Descriptions of the same contents as those described with reference to FIG. 5A and FIG. 5B may be omitted.

Referring to FIG. 6, the display panel 110 according to the embodiments of the present disclosure may include a substrate 111, an insulating layer 560 disposed on the substrate 111 and having a plurality of grooves GRV, a first lower electrode LE1 disposed on the insulating layer 560, and a first light emitting device ED1 disposed on the insulating layer 560 and including a first electrode E1 and a second electrode E2.

Referring to FIG. 6, the display panel 110 according to the embodiments of the present disclosure may further include a catching material CM, a second light emitting device ED2, and a second lower electrode LE2.

The catching material CM may be disposed inside a groove GRV adjacent to the first light emitting device ED1 among the plurality of grooves GRV of the insulating layer 560. Here, the groove GRV adjacent to the first light emitting device ED1 is a groove GRV located in the area of the first sub-pixel SP among the plurality of grooves GRV formed in the insulating layer 560, and may be a groove GRV provided for repairing the first sub-pixel SP.

The second light emitting device ED2 may be disposed in the area of the first sub-pixel SP including the first light emitting device ED1. The second light emitting device ED2 may function as a light emitting device of the first sub-pixel SP instead of the first light emitting device ED1 determined to be defective.

The second light emitting device ED2 may be disposed on a catching material CM applied or formed inside the groove GRV, which is a repair site formed in the area of the first sub-pixel SP, and may include a first electrode E1 and a second electrode E2.

The second lower electrode LE2 may be disposed on the first lower electrode LE1, and may be connected to the first lower electrode LE1. Here, a metal constituting the second lower electrode LE2 may be also referred to as a second lower electrode metal.

In the area where each of the first light emitting device ED1 and the second light emitting device ED2 is disposed, a metal pattern MP may exist on the second protective film 330 and the second electrode E2 of each of the first light emitting device ED1 and the second light emitting device ED2. The metal pattern MP may be the same metal as the second lower electrode LE2 (i.e., second lower electrode metal), and may be a metal pattern that is disconnected from the second lower electrode LE2 during the panel manufacturing process.

Each of the first light emitting device ED1 and the second light emitting device ED2 may have an undercut structure in which the lower portion of the intermediate layer 310 is sunken inward. Due to this, during the panel manufacturing process, when the second lower electrode metal is deposited to form the second lower electrode LE2, the second lower electrode metal may be cut or disconnected along the edges of each of the first light emitting device ED1 and the second light emitting device ED2, so that the second lower electrode LE2 and the metal pattern MP may be formed separately to be disconnected.

For example, the first lower electrode LE1 and the second lower electrode LE2 may be transparent electrodes. For another example, the first lower electrode LE1 and the second lower electrode LE2 may be reflective electrodes. For another example, the first lower electrode LE1 may be a reflective electrode, and the second lower electrode LE2 may be a transparent electrode. For example, if at least one of the first lower electrode LE1 and the second lower electrode LE2 is configured as a transparent electrode that can transmit light, at least one of the first lower electrode LE1 and the second lower electrode LE2 may be configured of a transparent metal material (e.g., transparent conductive material; TCO) such as ITO (Indium Tin Oxide) and IZO (Indium Zinc Oxide), but is not limited thereto.

As an example, the first lower electrode LE1 and the second lower electrode LE2 may be electrodes that are patterned identically using the same mask. As another example, the first lower electrode LE1 and the second lower electrode LE2 may be electrodes that are patterned differently using different masks. In the area where the first light emitting device ED1 and the second light emitting device ED2 are positioned, a metal pattern MP made of the same metal as the second lower electrode LE2 may be formed on each of the first light emitting device ED1 and the second light emitting device ED2. Here, the metal pattern MP disposed on each of the first light emitting device ED1 and the second light emitting device ED2 may be a metal that is disconnected from the second lower electrode LE2 during the panel manufacturing process.

If the first light emitting device ED1 is determined to be defective during the inspection process during the panel manufacturing process, a repair process may be performed on the first sub-pixel SP including the first light emitting device ED1.

The repair process for the first sub-pixel SP may include a process of forming a catching material CM, a second light emitting device ED2, and a second lower electrode LE2. That is, the catching material CM, the second light emitting device ED2, and the second lower electrode LE2 may be components formed according to the repair process.

Referring to FIG. 6, as described above, both the first light emitting device ED1 and the second light emitting device ED2 may be included in the first sub-pixel SP. The first light emitting device ED1 may be a defective light emitting device that is unable to emit light normally. The second light emitting device ED2 may be a light emitting device that replaces the first light emitting device ED1 and may be a normal light emitting device that is capable of emitting light normally.

Referring to FIG. 6, the first electrode E1 of the second light emitting device ED2 may be in contact with the second lower electrode LE2. The first electrode E1 of the first light emitting device ED1 may be in contact with the first lower electrode LE1.

The first electrode E1 of the second light emitting device ED2 and the second lower electrode LE2 may be connected to a side contact structure. That is, instead of the back surface of the first electrode E1 of the second light emitting device ED2 and the upper surface of the second lower electrode LE2 being connected, the side surface and upper surface of the first electrode E1 of the second light emitting device ED2 may be connected to the second lower electrode LE2.

Referring to FIG. 6, the catching material CM may have a thickness corresponding to the depth of the groove GRV of the insulating layer 560. For example, the catching material CM may include a viscous organic material. For example, the catching material CM may include photoacrylic.

During the repair process, the second light emitting device ED2 may be transferred onto the catching material CM filled in the groove GRV of the insulating layer 560. Accordingly, the height of the upper surface of the first light emitting device ED1 from the substrate 111 may correspond to the height of the upper surface of the second light emitting device ED2 from the substrate 111.

Referring to FIG. 6, the connection electrode CE may be disposed between the insulating layer 560 and the first lower electrode LE1. The connection electrode CE may electrically connect the first lower electrode LE1 to the source electrode S or the drain electrode D of the transistor TFT through the hole of the insulating layer 560. Here, the first lower electrode LE1 may be arranged on the insulating layer 560, and the transistor TFT may be disposed below the insulating layer 560.

A connection point between the connection electrode CE and the transistor TFT may be located between the first light emitting device ED1 and the second light emitting device ED2. Accordingly, the transistor TFT may be effectively connected to one of the first light emitting device ED1 and the second light emitting device ED2. As a result, it is possible to enable the effective driving of one of the first light emitting device ED1 and the second light emitting device ED2.

Referring to FIG. 6, at least one organic layer 570 and 580 may be disposed to surround the first light emitting device ED1 and the second light emitting device ED2. The at least one organic layer 570 and 580 may include the first organic layer 570 and the second organic layer 580. For example, each of the first organic layer 570 and the second organic layer 580 may include photoacrylic.

Referring to FIG. 6, the upper electrode UE may be disposed on at least one organic layer 570 and 580, and may be connected to the second electrode E2 of the first light emitting device ED1 and the second electrode E2 of the second light emitting device ED2. A metal pattern MP made of the same metal as the second lower electrode LE2 may exist between the upper electrode UE and the second electrode E2 of the second light emitting device ED2. The upper electrode UE may be connected to the metal pattern MP on the second light emitting device ED2, and the metal pattern MP may be connected to the second electrode E2 of the second light emitting device ED2, so that the upper electrode UE and the second electrode E2 of the second light emitting device ED2 may be electrically connected to each other.

Referring to FIG. 6, the upper electrode UE may be electrically connected to a power line 545 to which a common voltage is applied. For example, the common voltage applied to the power line 545 may be a low-potential common voltage VSS. In this case, the power line 545 may be a low-potential common voltage line VSSL or a wiring connected thereto. As another example, the common voltage applied to the power line 545 may be a high-potential common voltage VDD. In this case, the power line 545 may be a high-potential common voltage line VDDL or a wiring connected thereto.

For example, the first electrode E1 of the second light emitting device ED2 may be an anode electrode, and the second electrode E2 of the second light emitting device ED2 may be a cathode electrode. In this case, the first lower electrode LE1 and the second lower electrode LE2 may be anode wiring, and the upper electrode UE may be a cathode wiring.

As another example, the first electrode E1 of the second light emitting device ED2 may be a cathode electrode, and the second electrode E2 of the second light emitting device ED2 may be an anode electrode. In this case, the first lower electrode LE1 and the second lower electrode LE2 may be cathode wiring, and the upper electrode UE may be an anode wiring.

Each of the first light emitting device ED1 and the second light emitting device ED2 may include an intermediate layer 310 between the first electrode E1 and the second electrode E2.

The intermediate layer 310 may include an emission layer 313, a first semiconductor layer 311 between the first electrode E1 and the emission layer 313, and a second semiconductor layer 312 between the second electrode E2 and the emission layer 313.

Referring to FIG. 6, each of the first light emitting device ED1 and the second light emitting device ED2 may further include a first protective film 320 surrounding the side of the first semiconductor layer 311 and the side of the emission layer 313. Each of the first light emitting device ED1 and the second light emitting device ED2 may further include a second protective film 330 surrounding the second semiconductor layer 312.

Referring to FIG. 6, the first electrode E1 of each of the first light emitting device ED1 and the second light emitting device ED2 may be a portion having the largest area in each of the first light emitting device ED1 and the second light emitting device ED2. Therefore, the size of the light emitting device ED may be the same as the size SIZE_E1 of the first electrode E1.

Referring to FIG. 6, the first electrode E1 of each of the first light emitting device ED1 and the second light emitting device ED2 may include a lower electrode E1a having a first area, and an upper electrode E1b disposed on the lower electrode E1a and having a second area smaller than the first area.

Referring to FIG. 6, among the lower electrode E1a and the upper electrode E1b included in the first electrode E1 of the second light emitting device ED2, the lower electrode E1a may be in contact with the second lower electrode LE2. Here, the second light emitting device ED2 may be a light emitting device transferred during the repair process, and the second lower electrode LE2 may also be a newly formed electrode during the repair process.

The upper electrode E1b of the first electrode E1 of the second light emitting device ED2 may have a height greater than the height of the lower electrode E1a of the second light emitting device ED2. As a result, the second lower electrode LE2 may be easily interposed between the upper electrode E1b and the lower electrode E1a of the second light emitting device ED2, and as a result, the upper surface of the lower electrode E1a and the side surface of the upper electrode E1b and the second lower electrode LE2 may be well connected.

Among the lower electrode E1a and the upper electrode E1b included in the first electrode E1 of the first light emitting device ED1, the lower electrode E1a may be in contact with the first lower electrode LE1. Here, the first light emitting device ED1 is a light emitting device transferred before the repair process, and the first lower electrode LE1 may also be an electrode formed before the repair process.

Referring to FIG. 6, the first electrode E1 of the first light emitting device ED1 may be connected to the first lower electrode LE1 and the second lower electrode LE2.

Meanwhile, as described above, a metal pattern MP made of the same metal as the second lower electrode LE2 may exist on the first light emitting device ED1 and the second light emitting device ED2. The metal pattern MP existing on the first light emitting device ED1 and the second light emitting device ED2 may be physically and electrically separated from the second lower electrode LE2.

The metal pattern MP on the second light emitting device ED2 may be disposed between the upper electrode UE and the second electrode E2 of the second light emitting device ED2. That is, a lower surface of the metal pattern MP may be connected to the upper surface of the second electrode E2 of the second light emitting device ED2, and an upper surface of the metal pattern MP may be connected to the lower surface of the upper electrode UE. Accordingly, the upper electrode UE and the second electrode E2 of the second light emitting device ED2 may be electrically connected through the metal pattern MP on the second light emitting device ED2.

The first light emitting device ED1 may be a defective light emitting device that does not emit light at all. In this case, the sub-pixel SP including the first light emitting device ED1 may appear as a dark spot. That is, the first light emitting device ED1 may be a defective light emitting device that causes an abnormal dark spot on the screen.

If the first light emitting device ED1 is a defective light emitting device causing an abnormal dark spot on the screen, that is, if the first light emitting device ED1 is a defective light emitting device that does not emit light at all, the first electrode E1 of the first light emitting device ED1 may be connected to the first lower electrode LE1 and the second lower electrode LE2. Therefore, during repair processing, there is no need to cut the first electrode E1 of the first light emitting device ED1, which is a defective light emitting device, from the first lower electrode LE1 and the second lower electrode LE2.

Meanwhile, the first light emitting device ED1 may be a defective light emitting device that emits light abnormally brightly. In this case, the sub-pixel SP including the first light emitting device ED1 may appear as a bright spot. In other words, the first light emitting device ED1 may be a defective light emitting device that causes an abnormal bright spot defect on the screen.

Hereinafter, it will be described a case in which the first light emitting device ED1 is a defective light emitting device causing an abnormal bright spot on the screen with reference to FIG. 7.

FIG. 7 is a cross-sectional view of a display panel 110 according to embodiments of the present disclosure.

The first light emitting device ED1 is a light emitting device included in the first sub-pixel SP, and may be a defective light emitting device that emits abnormally bright light. In this case, the first sub-pixel SP including the first light emitting device ED1 may appear as a bright spot. In other words, the first light emitting device ED1 may be a defective light emitting device causing an abnormal bright spot defect on the screen.

For example, if the first electrode E1 and the second electrode E2 of the first light emitting device ED1 are short-circuited, a defective bright spot may occur.

If the first light emitting device ED1 is a defective light emitting device causing an abnormal bright spot defect on the screen, that is, if the first light emitting device ED1 is a defective light emitting device that emits abnormally bright light, the first electrode E1 of the first light emitting device ED1 is required to be not connected to the first lower electrode LE1 and the second lower electrode LE2.

Therefore, as shown in FIG. 7, during the repair process, the first electrode E1 of the first light emitting device ED1, which is a defective light emitting device, is required to be cut or disconnected from the first lower electrode LE1 and the second lower electrode LE2.

Depending on the result of the cutting process during the repair process, the first electrode E1 of the first light emitting device ED1 may be disconnected from the first lower electrode LE1 and the second lower electrode LE2.

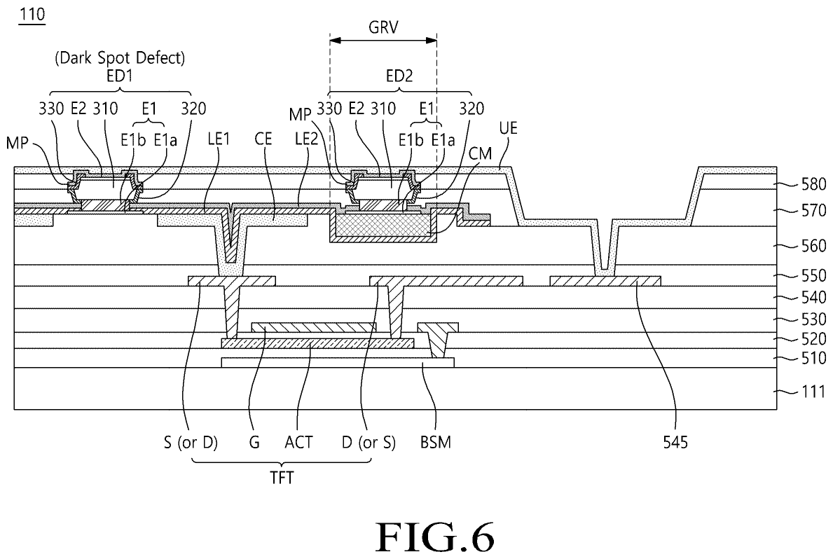

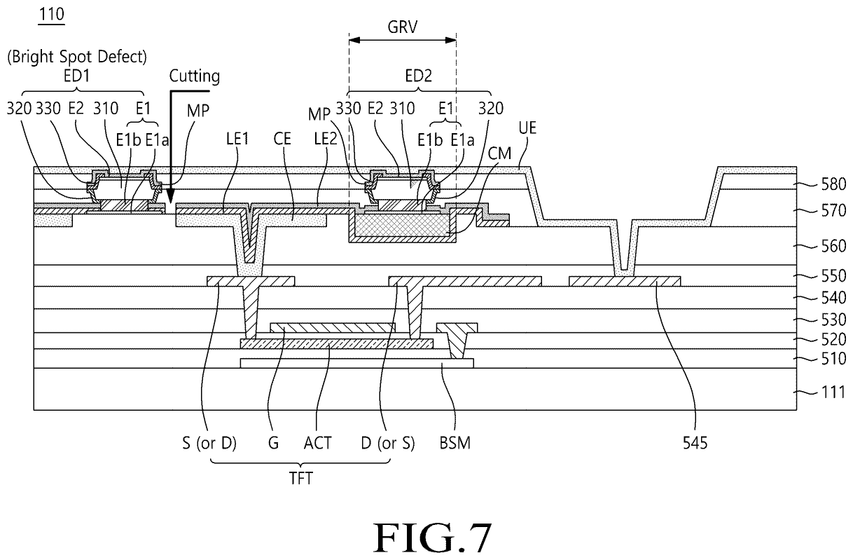

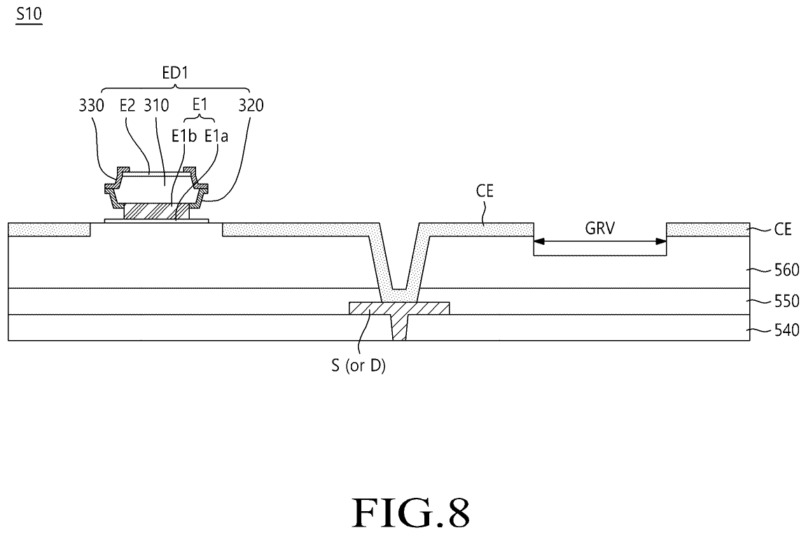

FIGS. 8 to 16 illustrate a manufacturing process of a display panel 110 according to embodiments of the present disclosure. In the following description, FIGS. 1 to 7 are also referred to.

Referring to FIGS. 8 to 11, the manufacturing process of the display panel 110 may include a first step (S10) of transferring light emitting devices ED including a first light emitting device ED1, a second step (S20) of forming a first lower electrode LE1, a third step (S30) of inspecting light emitting devices ED including the first light emitting device ED1, and, if the first light emitting device ED1 is determined to be normal in the third step (S30), a fourth step (S40) of forming organic layers 570 and 580 and an upper electrode UE.

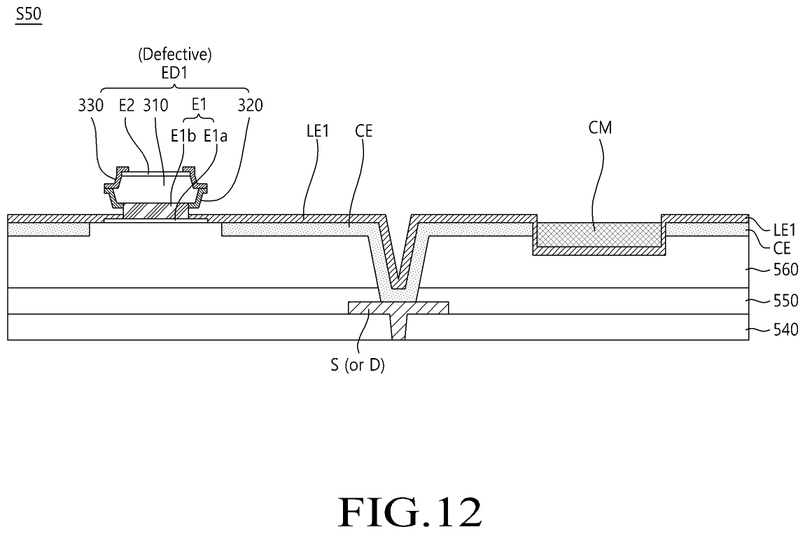

Referring to FIGS. 12 to 16, the manufacturing process of the display panel 110 may further include a fifth step (S50) of forming a catching material CM at a repair site if the first light emitting device ED1 is determined to be defective in the third step (S30), a sixth step (S60) of transferring a second light emitting device ED2 onto the catching material CM, a seventh step (S70) of forming a second lower electrode LE2, an eighth step (S80) of inspecting the second light emitting device ED2, and a ninth step (S90) of forming an organic layer 570 and 580 and an upper electrode UE.

Depending on the inspection result in the third step (S30), the fourth step (S40) may be performed, or the fifth to ninth steps (S50 to S90) may be performed. That is, if the first light emitting device ED1 is determined to be normal as a result of the inspection in the third step (S30), the fourth step (S40) may be performed. If the first light emitting device ED1 is determined to be defective as a result of the inspection in the third step (S30), the fourth step (S40) is not performed, and the fifth to ninth steps (S50 to S90) may be performed.

If the first light emitting device ED1 is determined to be defective as a result of the inspection in the third step (S30), this may mean that the sub-pixel SP including the first light emitting device ED1 is a defective sub-pixel.

Therefore, the fifth to ninth steps (S50 to S90) may be processing processes for repairing the sub-pixel SP including the first light emitting device ED1.

The manufacturing process of the display panel 110 briefly described above will be described in more detail with reference to FIGS. 8 to 16. For convenience of explanation, the substrate 111, a buffer layer 510, a gate insulating layer 520, a first interlayer insulating layer 530, and a transistor TFT are omitted from the cross-sectional views of FIGS. 8 to 16.

Referring to FIG. 8, the first step (S10) is a step of first transferring light emitting devices ED.

Before the transfer process of the first step (S10) is performed, a process of forming a transistor TFT may be performed.

In the process of forming a transistor TFT, an insulating film structure including a buffer layer 510, a gate insulating layer 520, a first interlayer insulating layer 530, a second interlayer insulating layer 540, and a passivation layer 550 may be formed on a substrate 111 in conjunction with the formation of a gate electrode G, a source electrode S, and a drain electrode D of the transistor TFT.

After the process of forming a transistor TFT is performed, a transfer preparation step for transferring light emitting devices ED may be performed. In the transfer preparation step, an insulating layer 560 corresponding to an adhesive layer may be formed on the passivation layer 550, and a connection electrode CE may be formed on the insulating layer 560.

In the transfer preparation step, the connection electrode CE may be electrically connected to the source electrode S or the drain electrode D of the transistor TFT through a hole of the insulating layer 560.

In addition, in the transfer preparation step, a groove GRV may be formed in the insulating layer 560. The groove GRV of the insulating layer 560 may be a repair site for repair processing that may be performed in the future.

After the transfer preparation step, the transfer process (e.g., first transfer process) of the first step (S10) may be performed, so that the light emitting devices ED including the first light emitting device ED1 may be transferred onto the insulating layer 560. In this case, the connection electrode CE may be open at the site where the light emitting devices ED are to be transferred. That is, the transferred light emitting devices ED and the connection electrode CE may not overlap with each other in the vertical direction.

The light emitting device ED may include a first electrode E1 and a second electrode E2, and an intermediate layer 310 between the first electrode E1 and the second electrode E2. The intermediate layer 310 may include a first semiconductor layer 311 disposed on the first electrode E1, an emission layer 313 disposed on the first semiconductor layer 311, and a second semiconductor layer 312 disposed on the emission layer 313.

The first electrode E1 may include a lower electrode E1a having a first area, and an upper electrode E1b disposed on the lower electrode E1a and having a second area smaller than the first area.

The light emitting device ED may further include a first protective film 320 covering each side of the first semiconductor layer 311 and the emission layer 313, and a second protective film 330 covering the side of the second semiconductor layer 312.

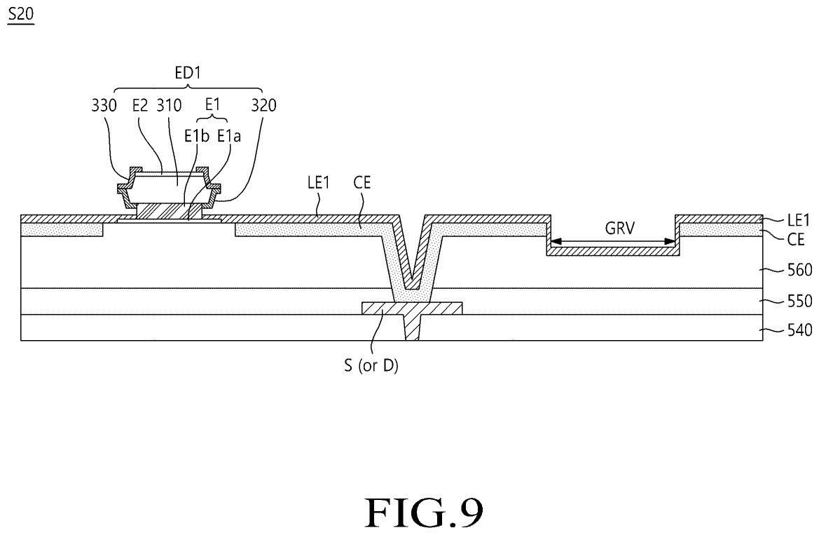

Referring to FIG. 9, in the second step (S20), a first lower electrode LE1 may be formed. In the second step (S20), the first lower electrode LE1 may be formed on the connection electrode CE and may be electrically connected to the connection electrode CE.

In the second step (S20), the first lower electrode LE1 may be electrically connected to the first electrode E1 of the first light emitting device ED1. For example, the first lower electrode LE1 may be electrically connected to the upper surface of the lower electrode E1a of the first electrode E1. The first lower electrode LE1 may be additionally electrically connected to the side surface of the upper electrode E1b of the first electrode E1.

In the second step (S20), the first lower electrode LE1 may be formed inside the groove GRV of the insulating layer 560. The first lower electrode LE1 may be arranged on the inner side surface of the groove GRV of the insulating layer 560, and may be extended to be disposed on the bottom of the groove GRV.

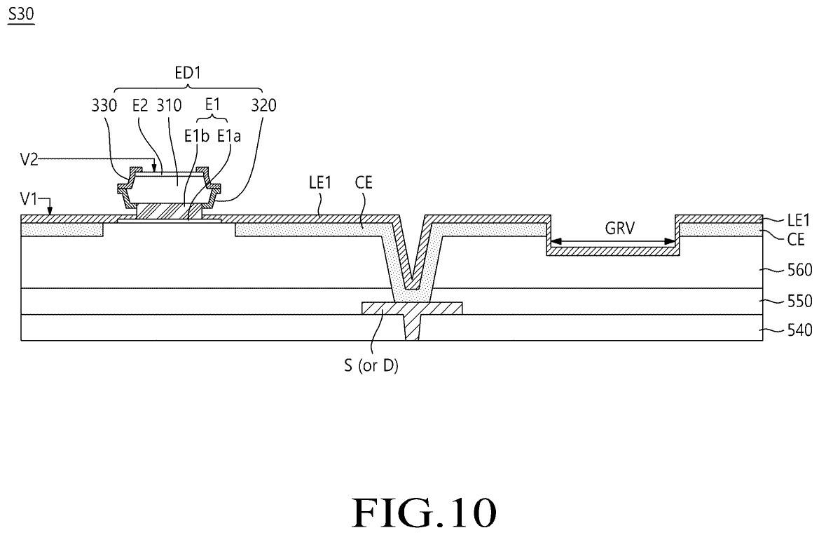

Referring to FIG. 10, in the third step (S30), an inspection may be performed on the light emitting devices ED including the first light emitting device ED1. The inspection in the third step (S30) may be a primary inspection to determine whether the light emitting devices ED that were first transferred are normal or defective.

For example, the inspection in the third step (S30) may be a lighting inspection to check whether the light emitting devices ED that were first transferred are able to emit light. The lighting inspection may be performed by applying a first inspection voltage V1 to the first lower electrode LE1 and applying a second inspection voltage V2 that is different from the first inspection voltage V1 to the second electrode E2 of each of the light emitting devices ED to check whether each of the light emitting devices ED is able to emit light. During the lighting inspection, light emitting devices ED that emit light within a set brightness range may be determined as normal, a light emitting device ED that does not emit light may be determined as a defective light emitting device with a dark spot defect, and a light emitting device ED that emit light with a brightness or a luminance exceeding the set brightness range may be determined as a defective light emitting device with a bright spot defect.

As a result of the inspection, it is possible to determine whether each of the light emitting devices ED is normal or defective. In addition, as a result of the inspection, the type of defect in the defective light emitting device ED among the light emitting devices ED may also be determined. The defect may include a dark spot defect where the light emitting device ED cannot emit light at all, and a bright spot defect where the light emitting device ED emits light abnormally brightly.

If the light emitting device ED is a defective light emitting device with a dark spot defect, the sub-pixel SP including the light emitting device ED with a dark spot defect may appear as an abnormal dark spot. If the light emitting device ED is a defective light emitting device with a bright spot defect, the sub-pixel SP including the light emitting device ED with a bright spot defect may appear as an abnormal bright spot.

If the inspection in the third step (S30) is performed and all light emitting devices ED including the first light emitting device ED1 are determined to be normal, the fourth step (S40) may be performed.

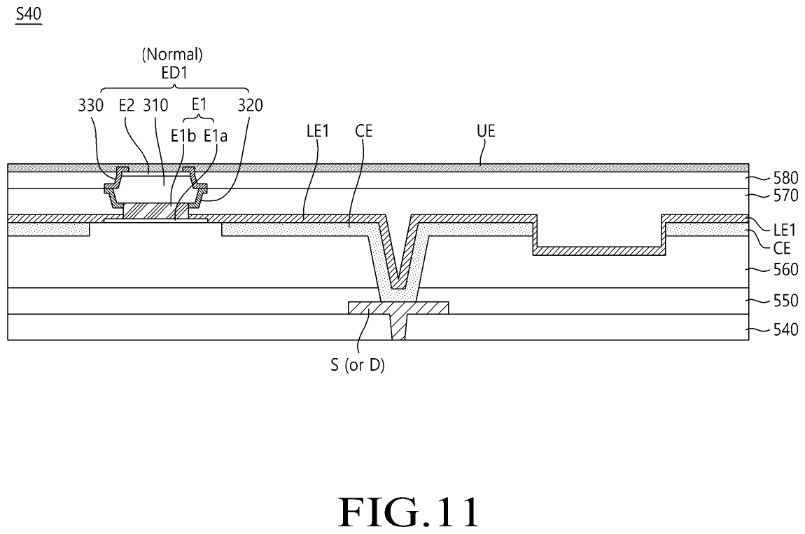

Referring to FIG. 11, in the fourth step (S40), a first organic layer 570 surrounding the light emitting devices ED including the first light emitting device ED1 may be formed, a second organic layer 580 may be formed on the first organic layer 570, and an upper electrode UE may be formed on the second organic layer 580.

The upper electrode UE may be electrically connected to the second electrode E2 of each of the light emitting devices ED including the first light emitting device ED1.

If the inspection in the third step (S30) is performed and the first light emitting device ED1 among the light emitting devices ED is determined to be defective, the fourth step (S40) may not be performed, and a repair process may be performed. The repair process may include the fifth to ninth steps (S50 to S90).

Referring to FIG. 12, in the fifth step (S50), a catching material CM may be applied within a groove GRV of an insulating layer 560 provided as a repair site. For example, the catching material CM may include an organic material such as photoacrylic.

For example, the height of the upper surface of the catching material CM may correspond to the height of the upper surface of the insulating layer 560 on which the first light emitting device ED1 is placed.

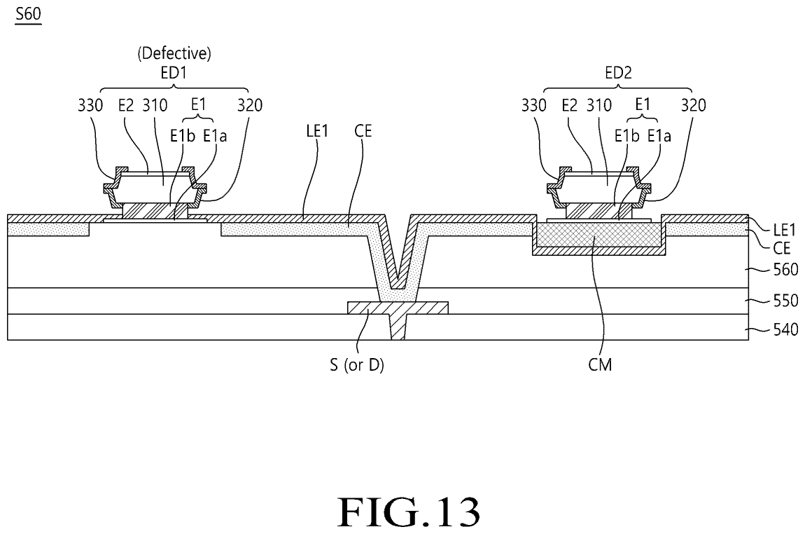

Referring to FIG. 13, in the sixth step (S60), a second light emitting device ED2 to replace the first light emitting device ED1 may be transferred onto the catching material CM. The transfer in the sixth step (S60) may be a secondary transfer for repair.

For example, the area of the upper surface of the catching material CM may be greater than or equal to the area (e.g., size) of the first electrode E1 of the second light emitting device ED2. For example, the area of the upper surface of the catching material CM may be greater than or equal to the area (e.g., size) of the lower electrode E1a of the first electrode E1 of the second light emitting device ED2. For example, the size of the groove GRV of the insulating layer 560 may be greater than or equal to the area (or size) of the first electrode of the second light emitting device ED2.

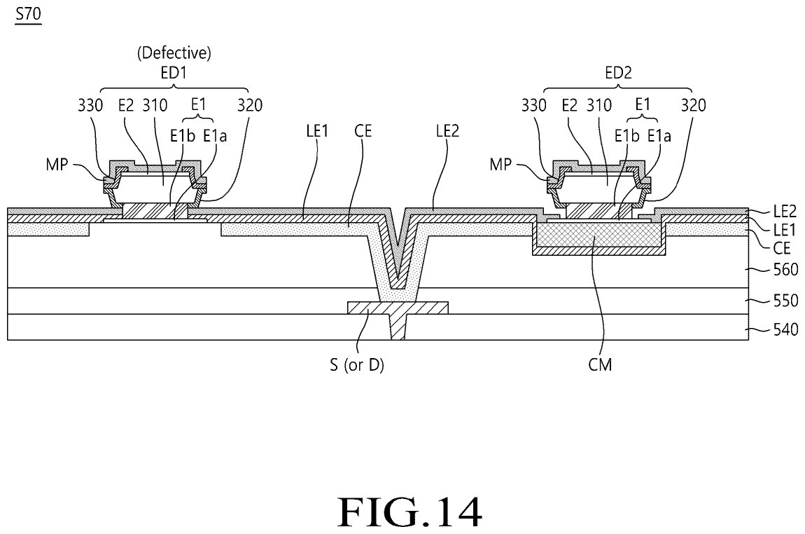

Referring to FIG. 14, in the seventh step (S70), a second lower electrode LE2 may be formed. The second lower electrode LE2 may be electrically connected to the first electrode E1 of the second light emitting device ED2. For example, the second lower electrode LE2 may be electrically connected to the upper surface and the side surface of the lower electrode E1a of the first electrode E1 of the second light emitting device ED2. The second lower electrode LE2 may be additionally electrically connected to a portion of the side surface of the upper electrode E1b of the first electrode E1 of the second light emitting device ED2.

When depositing the second lower electrode metal to form the second lower electrode LE2, a portion of the second lower electrode metal may be disposed on the first lower electrode LE1 to form the second lower electrode LE2, and another portion of the second lower electrode metal may be disposed on the first light emitting device ED1 and the second light emitting device ED2 to form the metal pattern MP.

The second lower electrode LE2 and the metal pattern MP may be physically disconnected by an undercut structure formed under the second protective film 330 and under the first protective film 320 of each of the first light emitting device ED1 and the second light emitting device ED2. As a result, it is possible to prevent an electrical short between the first electrode E1 and the second electrode E2 of each of the first light emitting device ED1 and the second light emitting device ED2.

Referring to FIG. 14, if the defect of the first light emitting device ED1 is a dark spot defect, the first electrode E1 of the first light emitting device ED1 may be electrically connected to the first lower electrode LE1 and the second lower electrode LE2. Therefore, if the defect of the first light emitting device ED1 is a dark spot defect, it is not required a cutting process for disconnecting the electrical connection between the first electrode E1 of the first light emitting device ED1 and the first lower electrode LE1 and the second lower electrode LE2 in the seventh step (S70).

However, if the defect of the first light emitting device ED1 is a bright spot defect, the first electrode E1 of the first light emitting device ED1 should not be electrically connected to the first lower electrode LE1 and the second lower electrode LE2. Therefore, if the defect of the first light emitting device ED1 is a bright spot defect, the cutting process for disconnecting the electrical connection between the first electrode E1 of the first light emitting device ED1 and the first lower electrode LE1 and the second lower electrode LE2 may be performed in the seventh step (S70).

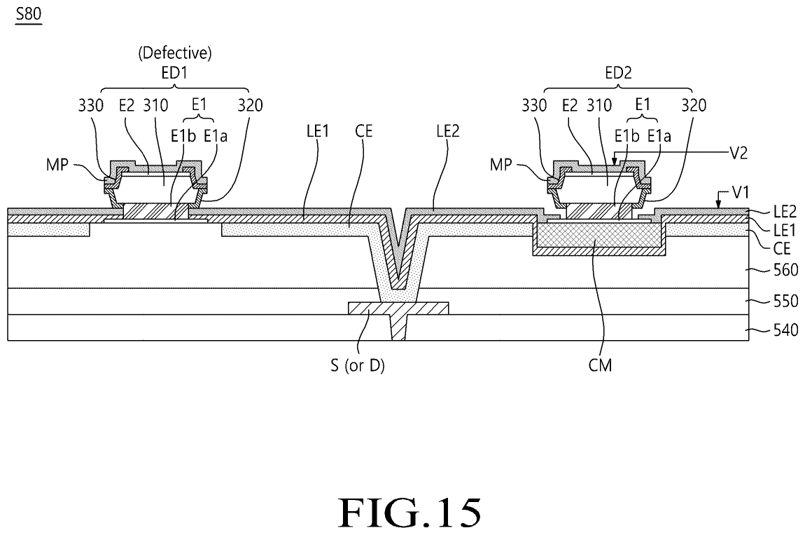

Referring to FIG. 15, in the eighth step (S80), an inspection may be performed to determine whether the second light emitting device ED2 transferred secondarily is normal or defective. The inspection in the eighth step (S80) may be a secondary inspection to determine whether the second light emitting device ED2 transferred secondarily is normal or defective.

For example, the inspection in the eighth step (S80) may be a lighting inspection to check whether the second light emitting device ED2 transferred secondarily is able to emit the light. The lighting inspection may be performed by applying a first inspection voltage V1 to the second lower electrode LE2 and applying a second inspection voltage V2 different from the first inspection voltage V1 to the second electrode E2 of the second light emitting device ED2 to check whether the second light emitting device ED2 emits light. During the lighting inspection, the second light emitting device ED2 that emits light within a set brightness range may be determined as a normal light emitting device, the second light emitting device ED2 that does not emit light may be determined to have a dark spot defect, and the second light emitting device ED2 that emits light with a brightness or luminance exceeding the set brightness range may be determined to have a bright spot defect.

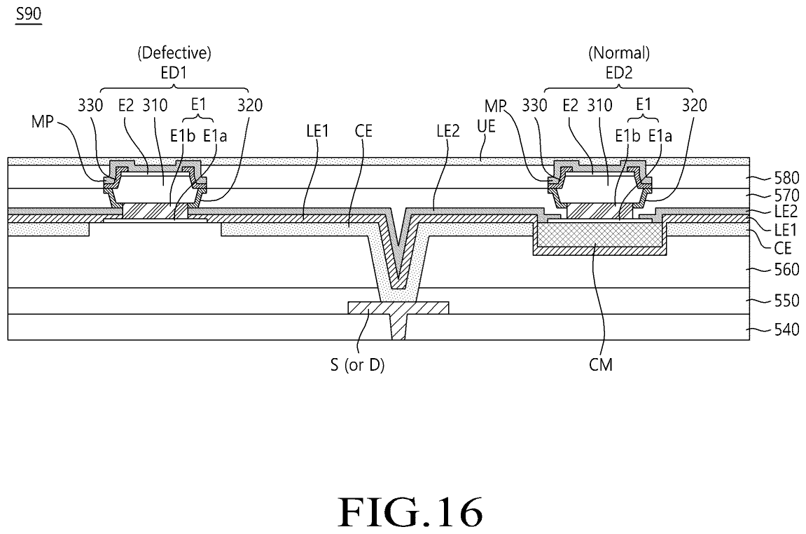

Referring to FIG. 16, if the second light emitting device ED2 is determined to be normal as a result of the test in the eighth step (S80), a ninth step (S90) of forming an organic layer 570 and 580 and an upper electrode UE may be performed.

Meanwhile, the upper electrode UE formed in the ninth step (S90) may be electrically connected to the second electrode E2 of the second light emitting device ED2 through a metal pattern MP made of the same metal as the second lower electrode LE2.

Meanwhile, if the inspection in the third step (S30) is performed and the first light emitting device ED1 is determined to be normal but other light emitting devices are determined to be defective, repair processing for the second sub-pixel including the defective light emitting device may be performed according to the fifth to ninth steps (S50 to S90).

Therefore, if the first light emitting device ED1 included in the first sub-pixel is determined to be normal during the panel manufacturing process but the light emitting device included in the second sub-pixel among the other sub-pixels is determined to be defective, repair processing for the second sub-pixel may be performed. Accordingly, in the display panel 110 in which manufacturing is completed, the first lower electrode LE1 and the second lower electrode LE2 may both be connected to the first electrode E1 of the normal first light emitting device ED1 (see FIG. 5B).

A display device according to the embodiments of the present disclosure may be described as follows.

A display device according to the embodiments of the present disclosure may include a substrate, an insulating layer disposed on the substrate and having a groove, a first lower electrode disposed on the insulating layer, a first light emitting device disposed on the insulating layer and including a first electrode and a second electrode, a catching material disposed inside the groove, a second light emitting device disposed on the catching material and including a first electrode and a second electrode, and a second lower electrode disposed on the first lower electrode and connected to the first electrode of the second light emitting device.

In the display device according to the embodiments of the present disclosure, the groove of the insulating layer may be a repair site to which a second light emitting device to replace the defective first light emitting device as a light emitting device of the corresponding sub-pixel is transferred during repair processing.

The first light emitting device may be a defective light emitting device that cannot emit normal light, and the second light emitting device may be a normal light emitting device capable of emitting normal light.

The first electrode of the second light emitting device may be in contact with the second lower electrode, and the first electrode of the first light emitting device may be in contact with the first lower electrode. That is, the first electrode of the second light emitting device may be connected to the second lower electrode, and the first electrode of the first light emitting device may be connected to the first lower electrode.

The catching material may have a thickness corresponding to the depth of the groove. Accordingly, the second light emitting device may be disposed at a height equivalent to that of the first light emitting device.

The catching material may include a viscous organic material. Accordingly, the second light emitting device may be stably settled on the catching material.

A height of an upper surface of the first light emitting device from the substrate may correspond to a height of an upper surface of the second light emitting device from the substrate.

The display device according to the embodiments of the present disclosure may further include a transistor disposed under the insulating layer, and a connection electrode disposed between the insulating layer and the first lower electrode.

The connection electrode may electrically connect the first lower electrode to a source electrode or a drain electrode of the transistor through a hole of the insulating layer. For example, the connection electrode may be a reflective electrode. Accordingly, the efficiency with which light emitted from the second light emitting device is emitted to the front surface of the display panel may be increased.

A connection point between the connection electrode and the transistor may be located between the first light emitting device and the second light emitting device. Accordingly, it is possible to efficiently drive the second light emitting device according to the repair process.

In the display device according to embodiments of the present disclosure, each of the first light emitting device and the second light emitting device may be a vertical light-emitting diode.

The display device according to the embodiments of the present disclosure may further include at least one organic layer surrounding the first light emitting device and the second light emitting device, and an upper electrode disposed on the at least one organic layer and connected to the second electrode of the first light emitting device and the second electrode of the second light emitting device.

Each of the first light emitting device and the second light emitting device may include an intermediate layer disposed between the first electrode and the second electrode. The intermediate layer may include an emission layer, a first semiconductor layer between the first electrode and the emission layer, and a second semiconductor layer between the second electrode and the emission layer.

The emission layer may be disposed closer to the first semiconductor layer than to the second semiconductor layer, or may be disposed closer to the second semiconductor layer than to the first semiconductor layer.

Each of the first light emitting device and the second light emitting device may further include a first protective film surrounding a side surface of the first semiconductor layer and a side surface of the emission layer.

Each of the first light emitting device and the second light emitting device may further include a second protective film surrounding the second semiconductor layer.

For example, both the first protective film and the second protective film may be provided. In another example, among the first protective film and the second protective film, only the first protective film may be provided.

If both the first protective film and the second protective film are provided, the first protective film and the second protective film may be integrally formed.

The first electrode of each of the first light emitting device and the second light emitting device may have a size larger than the size of other parts of each of the first light emitting device and the second light emitting device. Accordingly, the first light emitting device may be stably settled on the insulating layer.

In addition, the first electrode of the second light emitting device may have the same size as the size of the second light emitting device, so that the first electrode of the second light emitting device may be more accurately connected to the second lower electrode.

The first electrode of each of the first light emitting device and the second light emitting device may include a lower electrode having a first area, and an upper electrode disposed on the lower electrode and having a second area smaller than the first area. Accordingly, the first light emitting device can be stably settled on the insulating layer. In addition, the lower electrode of the first electrode of the second light emitting device may have the same size as the size of the second light emitting device or may have a larger size than other parts of the second light emitting device, so that the lower electrode of the first electrode of the second light emitting device may be more accurately connected to the second lower electrode.

Among the lower electrode and the upper electrode included in the first electrode of the second light emitting device, the lower electrode may be in contact with the second lower electrode. Among the lower electrode and the upper electrode included in the first electrode of the second light emitting device, the lower electrode may be electrically connected to the second lower electrode.

An upper surface of the upper electrode of each of the first light emitting device and the second light emitting device may have a smaller area than a lower surface of the intermediate layer (e.g., the first semiconductor layer) of each of the first light emitting device and the second light emitting device. As a result, an undercut structure may be formed in which a lower portion (e.g., the lower portion of the first protective film 320) of each of the first light emitting device and the second light emitting device is sunken.

A metal pattern may be further disposed on the second light emitting device. The metal pattern may include the same metal as the second lower electrode, and may be physically and electrically separated or disconnected from the second lower electrode.

The metal pattern on the second light emitting device may be disposed between the upper electrode and the second electrode of the second light emitting device. That is, the lower surface of the metal pattern may be connected to an upper surface of the second electrode of the second light emitting device, and an upper surface of the metal pattern may be connected to the lower surface of the upper electrode. Accordingly, the upper electrode and the second electrode of the second light emitting device may be electrically connected through the metal pattern on the second light emitting device.

The lower electrode among the lower electrode and the upper electrode included in the first electrode of the first light emitting device may be in contact with the first lower electrode. The lower electrode among the lower electrode and the upper electrode included in the first electrode of the first light emitting device may be connected to the first lower electrode.

If the first light emitting device has a dark spot defect, the first electrode of the first light emitting device may be connected to the first lower electrode and the second lower electrode.

If the first light emitting device has a bright spot defect, the first electrode of the first light emitting device may be disconnected from the first lower electrode and the second lower electrode. This may be a result of cutting processing during repair processing.

A display device according to embodiments of the present disclosure may include a substrate, an insulating layer disposed on the substrate and having a groove, a first lower electrode disposed on the insulating layer, a first light emitting device disposed on the insulating layer and including a first electrode and a second electrode, at least one organic layer disposed to surround the first light emitting device and fill the inside of the groove, and an upper electrode disposed on at least one organic layer.

According to embodiments of the present disclosure, a groove of the insulating layer may be a repair site to which a second light emitting device, which replaces the first light emitting device as a light emitting device of a corresponding sub-pixel, is transferred during repair processing.

The first electrode of the first light emitting device may be connected to the first lower electrode.

The second electrode of the first light emitting device may be connected to the upper electrode.

The first electrode of the first light emitting device may have a size equal to that of the first light emitting device or a size larger than that of another portion of the first light emitting device. Accordingly, the first light emitting device can be stably settled on the insulating layer.

The light emitting device according to the embodiments of the present disclosure may have a side contact structure.

A light emitting device according to the embodiments of the present disclosure may include a first electrode, a first semiconductor layer on the first electrode, an emission layer on the first semiconductor layer, a second semiconductor layer on the emission layer, and a second electrode on the second semiconductor layer. The first electrode may include a lower electrode having a first area, and an upper electrode disposed on the lower electrode and having a second area smaller than the first area.

The upper electrode may have a height greater than the height of the lower electrode.

An upper surface of the upper electrode may have a smaller area than a lower surface of the first semiconductor layer.

The display panel may further include a second lower electrode disposed on the first lower electrode if repair processing is performed on other sub-pixels during panel manufacturing even if the first light emitting device is normal. That is, the first electrode of the normal first light emitting device may be connected to the first lower electrode and the second lower electrode. That is, if even one of all light emitting devices disposed on the display panel is defective, the second lower electrode may be disposed on the first lower electrode.

According to the embodiments of the present disclosure described above, it is possible to provide a display device having a structure capable of easily repairing a sub-pixel including a defective light emitting device even if a defect occurs in a light emitting device disposed on a display panel.

According to the embodiments of the present disclosure, it is possible to provide a display device having a structure capable of repairing both a dark spot defect and a bright spot defect of the light emitting device even if a defect occurs in a light emitting device disposed on a display panel.

According to the embodiments of the present disclosure, it is possible to provide a light emitting device having an electrode structure (e.g., a structure of a first electrode) capable of easily performing a repair process.

According to the embodiments of the present disclosure, it is possible to provide a light emitting device having a structure capable of the side contact with an electrode (for example, a first lower electrode or a second lower electrode) on a display panel.

According to the embodiments of the present disclosure, it is possible to enable the process optimization by effectively repairing a sub-pixel including a defective light emitting device without a significant change in the panel structure.

In addition, according to the embodiments of the present disclosure, since it is not necessary to adopt a redundancy structure for additionally transferring expensive light emitting device in preparation for a defective light emitting device, so that it is possible to reduce the size and the weight of the display panel, simplify the design of the display panel, and significantly reduce the product price.

The display device according to the embodiments of the present disclosure may be included in various devices or electronic devices. For example, the various electronic devices may include wearable devices such as smart watches, mobile devices, laptops, and monitors or TVs.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention.

What is claimed is:

1. A display device comprising:
a substrate;
an insulating layer on the substrate, the insulating layer having a groove;
a first lower electrode on the insulating layer;
a first light emitting device on the insulating layer, the first light emitting device including a first electrode and a second electrode;
a catching material inside the groove;
a second light emitting device on the catching material, the second light emitting device including a first electrode and a second electrode; and
a second lower electrode on the first lower electrode, the second lower electrode connected to the first electrode of the second light emitting device.

2. The display device of claim 1, wherein the first light emitting device is a defective light emitting device that does not emit normal light, and the second light emitting device is a normal light emitting device emitting normal light.

3. The display device of claim 1, wherein the first electrode of the second light emitting device is connected to the second lower electrode, and the first electrode of the first light emitting device is connected to the first lower electrode.

4. The display device of claim 1, wherein the catching material has viscosity and a thickness corresponding to a depth of the groove.

5. The display device of claim 1, further comprising:
a transistor under the insulating layer; and
a connection electrode between the insulating layer and the first lower electrode, the connection electrode electrically connecting the first lower electrode to a source electrode or a drain electrode of the transistor through a hole of the insulating layer,
wherein a connection point between the connection electrode and the transistor is located between the first light emitting device and the second light emitting device.

6. The display device of claim 1, further comprising:
at least one organic layer surrounding the first light emitting device and the second light emitting device; and
an upper electrode disposed on the at least one organic layer, the upper electrode connected to the second electrode of the first light emitting device and the second electrode of the second light emitting device.

7. The display device of claim 6, further comprising a metal pattern between the second electrode of the second light emitting device and the upper electrode,
wherein the metal pattern includes a same metal as the second lower electrode.

8. The display device of claim 6, wherein each of the first light emitting device and the second light emitting device includes an intermediate layer between the first electrode and the second electrode,
wherein the intermediate layer includes:
an emission layer;
a first semiconductor layer between the first electrode and the emission layer; and
a second semiconductor layer between the second electrode and the emission layer,
wherein the emission layer is disposed closer to the first electrode than to the second electrode, or closer to the second electrode than to the first electrode.

9. The display device of claim 8, wherein each of the first light emitting device and the second light emitting device further includes a first protective film surrounding a side surface of the first semiconductor layer and a side surface of the emission layer.

10. The display device of claim 9, wherein each of the first light emitting device and the second light emitting device further includes a second protective film surrounding the second semiconductor layer.

11. The display device of claim 10, wherein the first protective film is disposed on a first side of the intermediate layer,
wherein the second protective film is disposed on a second side of the intermediate layer,
wherein the first protective film and the second protective film protrude outwardly away from the intermediate layer while being in contact with each other at a boundary between the first side and the second side.

12. The display device of claim 1, wherein the first electrode of each of the first light emitting device and the second light emitting device has a size equal to a size of each of the first light emitting device and the second light emitting device.

13. The display device of claim 1, wherein the first electrode of each of the first light emitting device and the second light emitting device includes:
a lower electrode having a first area; and
an upper electrode on the lower electrode, the upper electrode having a second area smaller than the first area.

14. The display device of claim 13, wherein, among the lower electrode and the upper electrode included in the first electrode of the second light emitting device, the lower electrode is connected to the second lower electrode.

15. The display device of claim 13, wherein, among the lower electrode and the upper electrode included in the first electrode of the first light emitting device, the lower electrode is connected to the first lower electrode.

16. The display device of claim 1, wherein the first electrode of the first light emitting device is connected to the first lower electrode and the second lower electrode.

17. The display device of claim 1, wherein the first electrode of the first light emitting device is disconnected from the first lower electrode and the second lower electrode.

18. A light emitting device comprising:
a first electrode;
a first semiconductor layer on the first electrode;
an emission layer on the first semiconductor layer;
a second semiconductor layer on the emission layer; and
a second electrode on the second semiconductor layer,
wherein the first electrode includes:
a lower electrode having a first area, and
an upper electrode on the lower electrode, the upper electrode having a second area smaller than the first area.

19. The light emitting device of claim 18, wherein the upper electrode has a height greater than a height of the lower electrode.

20. The light emitting device of claim 18, wherein an upper surface of the upper electrode has a smaller area than a lower surface of the first semiconductor layer.

21. A display device comprising:
a first light emitting device including a first electrode and a second electrode;
a second light emitting device including a third electrode and a fourth electrode;
a driving transistor configured to drive the first light emitting device and/or the second light-emitting device;
a first lower electrode electrically connected to the driving transistor, at least a part of the first lower electrode in contact with the first light emitting device, and the first lower electrode not in contact with the second light emitting device; and
a second lower electrode disposed on the first lower electrode, at least a part of the second lower electrode in contact with the first light emitting device, and the second lower electrode also in contact with the second light emitting device.

22. The display device of claim 21, wherein:
the first electrode of the first light emitting device includes a first part, and a second part on the first part, the first part being wider in size than the second part;
the third electrode of the second light emitting device includes a third part, and a fourth part on the third part, the third part being wider in size than the fourth part;
the at least part of the first lower electrode is in contact with the first part and the second part of the first electrode of the first light emitting device; and
the at least a part of the second lower electrode is in contact with the first part and the second part of the first electrode of the first light emitting device, and the second lower electrode is also in contact with the third part and the fourth part of the third electrode of the second light emitting device.

23. The display device of claim 22, wherein the second lower electrode is in contact with a side surface and a top surface of the third part and with a side surface of the fourth part.

24. The display device of claim 21, wherein the first light emitting device is a defective light emitting device that does not emit normal light, and the second light emitting device is a normal light emitting device emitting normal light.

25. The display device of claim 21, wherein:
each of the first light emitting device and the second light emitting device further includes a first protective film surrounding a side surface of a lower part of each of the first light emitting device and the second light emitting device;
each of the first light emitting device and the second light emitting device further includes a second protective film surrounding a side surface of an upper part of each of the first light emitting device and the second light emitting device; and
the first protective film and the second protective film protrude outwardly away from the first light emitting device and the second light emitting device while being in contact with each other at a boundary between the upper part and the lower part.

26. The display device of claim 21, wherein another part of the first lower electrode other than at least the part of the first lower electrode is electrically disconnected from the first light emitting device.
